(19) United States
(12) Patent Application Publication
(10) Pub. No.: US 2025/0120114 A1
(43) Pub. Date: Apr. 10, 2025

(54) INTEGRATED CIRCUIT SEMICONDUCTOR DEVICE

(71) Applicant: Samsung Electronics Co., Ltd., Suwon-si (KR)

(72) Inventors: Cheolsoon Jeong, Suwon-si (KR); Sangjung Kang, Suwon-si (KR); Jido Ryu, Suwon-si (KR); Hwasung Rhee, Suwon-si (KR); Hochul Lim, Suwon-si (KR)

(21) Appl. No.: 18/663,238

(22) Filed: May 14, 2024

(30) Foreign Application Priority Data
Oct. 4, 2023 (KR) 10-2023-0131939

(51) Int. Cl. H01L 29/78; H01L 27/092; H01L 29/417; H01L 29/423; H01L 29/66

(52) U.S. Cl. CPC H10D 30/6211; H10D 30/6219; H10D 64/021; H10D 64/513; H10D 84/853

(57) ABSTRACT

An integrated circuit semiconductor device includes an active fin on a substrate, gate structures apart from one another on the active fin, an interlayer insulation layer to insulate the gate structures on the active fin, gate contacts apart from one another on the gate structures, active contacts apart from one another at both sides of the gate structures, the active contacts passing through the interlayer insulation layer and contacting the active fin, an etch stopping layer on the gate structures, the interlayer insulation layer, the gate contacts, and the active contacts, and diffusion break regions between the active contacts, the diffusion break regions being buried in gate trenches passing through the etch stopping layer and the interlayer insulation layer and in fin recesses cutting the active fin under the gate trenches.

### CROSS-REFERENCE TO RELATED APPLICATION

This application is based on and claims priority under 35 U.S.C. § 119 to Korean Patent Application No. 10-2023-0131939, filed on Oct. 4, 2023, in the Korean Intellectual Property Office, the disclosure of which is incorporated by reference herein in its entirety.

### BACKGROUND

The inventive concept relates generally to an integrated circuit semiconductor device, and more particularly, to an integrated circuit semiconductor device including a plurality of contacts and a plurality of diffusion break regions.

Integrated circuit semiconductor devices need a plurality of contacts for electrical connections with active regions or gate structures. Also, integrated circuit semiconductor devices need a plurality of diffusion break regions for preventing the diffusion of impurity elements included in active regions. As integrated circuit semiconductor devices are highly integrated, it is very difficult to form reliable contacts or diffusion break regions.

### SUMMARY

The inventive concept provides an integrated circuit semiconductor device in which a plurality of contacts and a plurality of diffusion break regions are reliably formed.

According to an aspect of the inventive concept, there is provided an integrated circuit semiconductor device including an active fin on the substrate, a plurality of gate structures spaced apart from one another on the active fin, an interlayer insulation layer configured to insulate the plurality of gate structures on the active fin, a plurality of gate contacts spaced apart from one another on the plurality of gate structures, a plurality of active contacts spaced apart from one another at both sides of the plurality of gate structures, the plurality of active contacts passing through the interlayer insulation layer and contacting the active fin, an etch stopping layer on the plurality of gate structures, the interlayer insulation layer, the plurality of gate contacts, and the plurality of active contacts, and a plurality of diffusion break regions between the plurality of active contacts, the plurality of diffusion break regions being buried in gate trenches passing through the etch stopping layer and the interlayer insulation layer and in fin recesses cutting the active fin under the gate trenches.

According to another aspect of the inventive concept, there is provided an integrated circuit semiconductor device including a substrate, a plurality of active fins extending in a first direction on the substrate and arranged apart from one another in a second direction perpendicular to the first direction, a plurality of gate structures extending in the second direction on the plurality of active fins and arranged apart from one another in the first direction, an interlayer insulation layer configured to insulate the plurality of gate structures on the plurality of active fins, a plurality of gate contacts on the plurality of gate structures on the plurality of active fins and arranged apart from one another in the first direction and the second direction, a plurality of active contacts extending in the second direction at both sides of the plurality of gate structures and arranged apart from one another in the first direction, the plurality of active contacts passing through the interlayer insulation layer and contacting the plurality of active fins, an etch stopping layer on the plurality of gate structures, the interlayer insulation layer, the plurality of gate contacts, and the plurality of active contacts, and a plurality of diffusion break regions between the plurality of active contacts, the plurality of diffusion break regions being buried in gate trenches passing through the etch stopping layer and the interlayer insulation layer and in fin recesses cutting the plurality of active fins under the gate trenches.

According to another aspect of the inventive concept, there is provided an integrated circuit semiconductor device including a substrate including a first region and a second region, a plurality of active fins extending in a first direction in the first region and the second region and arranged apart from one another in a second direction perpendicular to the first direction, a plurality of gate structures extending in the second direction on the plurality of active fins in the first region and the second region and arranged apart from one another in the first direction, an interlayer insulation layer configured to insulate the plurality of gate structures on the plurality of active fins in the first region and the second region, a plurality of gate contacts on the plurality of gate structures on the plurality of active fins in the first region and the second region and arranged apart from one another in the first direction and the second direction, a plurality of active contacts extending in the second direction at both sides of the plurality of gate structures in the first region and the second region and arranged apart from one another in the first direction, the plurality of active contacts passing through the interlayer insulation layer and contacting the plurality of active fins, an etch stopping layer on the plurality of gate structures, the interlayer insulation layer, the plurality of gate contacts, and the plurality of active contacts in the first region and the second region, a plurality of single diffusion break regions between the plurality of active contacts of the first region, the plurality of single diffusion break regions being buried in first gate trenches passing through the etch stopping layer and the interlayer insulation layer and in first fin recesses cutting the plurality of active fins under the first gate trenches, and a plurality of double diffusion break regions between the plurality of active contacts of the second region, the plurality of double diffusion break regions including an upper diffusion break region buried in second gate trenches passing through the etch stopping layer and the interlayer insulation layer and a lower diffusion break region buried in second fin recesses cutting the plurality of active fins under the upper diffusion break region.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1 is a schematic layout of a partial region of an example integrated circuit semiconductor device according to an embodiment;

FIG. 2A is a cross-sectional view of the example integrated circuit semiconductor device shown in FIG. 1, taken along line II-II′;

FIG. 2B is a partial enlarged cross-sectional view of the example integrated circuit semiconductor device shown in FIG. 2A;

FIGS. 3A to 11 are cross-sectional views depicting intermediate processes in an example method of manufacturing the integrated circuit semiconductor device of FIGS. 2A and 2B;

FIG. 12 is a cross-sectional view of a partial region of an integrated circuit semiconductor device according to an embodiment;

FIGS. 13 to 16 are cross-sectional views depicting intermediate processes in an example method of manufacturing the integrated circuit semiconductor device of FIG. 12;

FIG. 17 is a schematic plan view layout of a partial region of an example integrated circuit semiconductor device according to an embodiment;

FIG. 18A is a cross-sectional view of the example integrated circuit semiconductor device shown in FIG. 17 taken along line A-A′;

FIG. 18B is a cross-sectional view of the example integrated circuit semiconductor device shown in FIG. 17 taken along line B-B′; and

FIGS. 19A to 24B are cross-sectional views depicting intermediate processes in an example method of manufacturing the integrated circuit semiconductor device of FIGS. 18A and 18B.

### DETAILED DESCRIPTION

Hereinafter, embodiments will be described in detail with reference to the accompanying drawings. The following embodiments may be implemented as only one arbitrary embodiment, and the following embodiments may also be implemented by a combination of one or more embodiments. Therefore, it is not construed that the inventive concept is limited to one embodiment.

It will be understood that, although the ordinal terms such as first, second, etc. may be used throughout this specification to describe various elements, these elements should not be limited by these terms. Rather, these terms are used merely to distinguish one element from another and are not intended to convey any particular order of the elements unless specifically stated. For example, a first element could be termed a second element, and, similarly, a second element could be termed a first element, without departing from the scope of the present inventive concept.

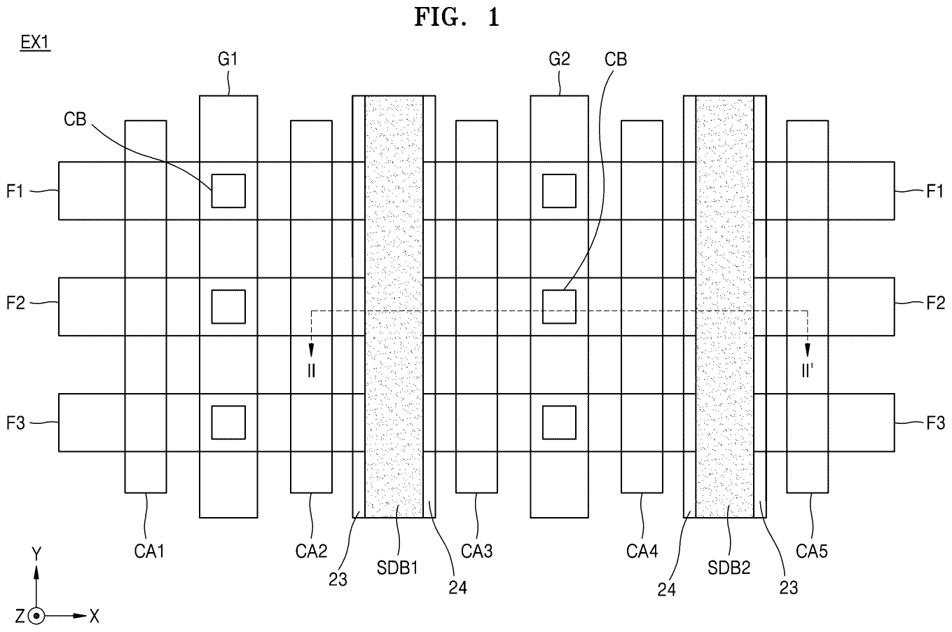

FIG. 1 is a schematic layout of a partial region of an example integrated circuit semiconductor device EX1 according to an embodiment of the present disclosure.

In detail, the integrated circuit semiconductor device EX1 may include active fins F1 to F3, gate structures G1 and G2, gate contacts CB, active contacts CA1 to CA5, diffusion break regions SDB1 and SDB2, and dummy spacers 23 and 24.

The active fins F1 to F3 may extend in a first direction (an X direction) parallel to an upper surface of a substrate (not explicitly shown) in which the active fins F1 to F3 may be formed. The active fins F1 to F3 may be arranged apart from one another in a second direction (a Y direction) parallel to the upper surface of the substrate and intersecting the first direction (the X direction). The active fins F1 to F3 may include a long side which is formed in the first direction and a short side which is formed in the second direction.

The gate structures G1 and G2 may extend in the second direction on the active fins F1 to F3. The gate structures G1 and G2 may be arranged apart from each other in the first direction. The gate structures G1 and G2 may include a first gate structure G1 and a second gate structure G2.

The gate contacts CB may be disposed on the gate structures G1 and G2 on the active fins F1 to F3. The gate contacts CB may be arranged apart from each other in the first direction and the second direction.

The active contacts CA1 to CA5 may be disposed at both (i.e., opposite) sides of the gate structures G1 and G2 in the first direction. The active contacts CA1 to CA5 may extend in the second direction. The active contacts CA1 to CA5 may be arranged apart from each other in the first direction. The active contacts CA1 to CA5 may contact the active fins F1 to F3. The term “contact” (or “contacting,” or like terms such as “connect” or “connecting”), as may be used herein, is intended to refer to a physical and/or electrical connection between two or more elements, and may include other intervening elements unless specified otherwise. As used herein, the term “and/or” includes any and all combinations of one or more of the associated listed items.

In an embodiment, the active contacts CA3 and CA4 may be between the diffusion break regions SDB1 and SDB2 in the first direction. The active contacts CA2 and CA3 may be disposed at both (opposite) sides of the diffusion break region SDB1 in the first direction. The active contacts CA4 and CA5 may be disposed at both (opposite) sides of the diffusion break region SDB2 in the first direction.

The diffusion break regions SDB1 and SDB2 may be formed between the active contacts CA2 and CA3 and between the active contacts CA4 and CA5 in the first direction. The diffusion break regions SDB1 and SDB2 may extend in the second direction. The diffusion break regions SDB1 and SDB2 may be arranged apart from each other in the first direction. The diffusion break regions SDB1 and SDB2 may be single diffusion break regions. The diffusion break regions SDB1 and SDB2 may include a first single diffusion break region SDB1 and a second single diffusion break region SDB2.

The dummy spacers 23 and 24 may be disposed at opposite sides of the diffusion break regions SDB1 and SDB2. The dummy spacers 23 and 24 may be arranged apart from each other in the first direction. The dummy spacers 23 and 24 may extend in the second direction on the active fins F1 to F3.

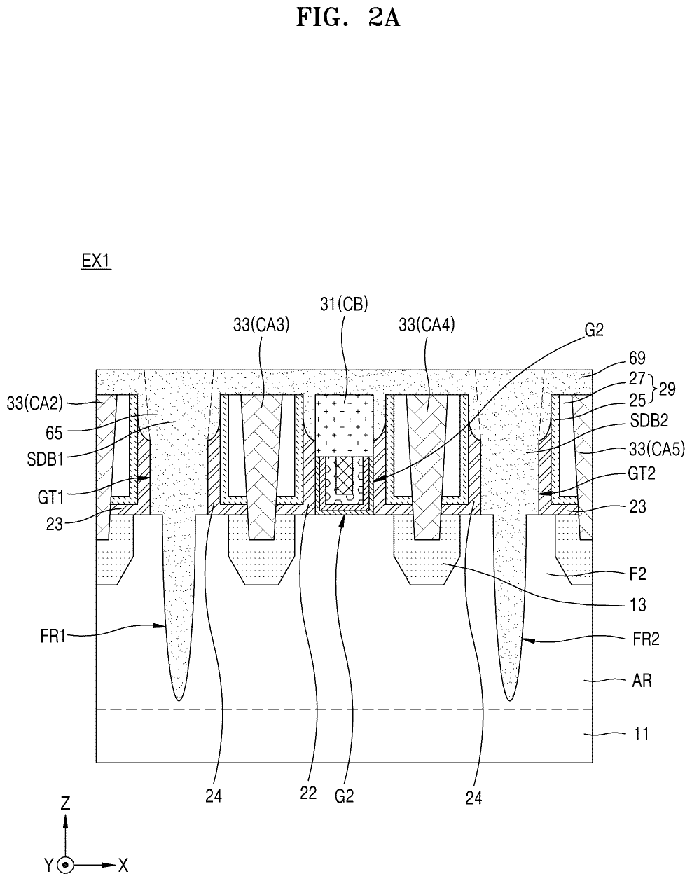

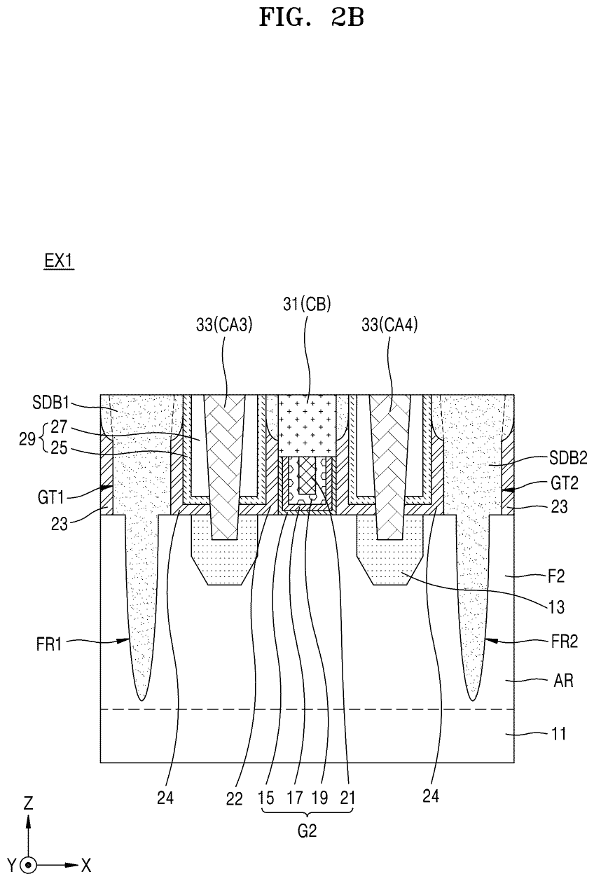

FIG. 2A is a cross-sectional view of the example integrated circuit semiconductor device EX1 shown in FIG. 1 taken along line II-II′, and FIG. 2B is a partial enlarged view of FIG. 2A.

In detail, with reference to FIGS. 2A and 2B, the integrated circuit semiconductor device EX1 may include a substrate 11, an active region AR, an active fin F2, a gate structure G2, source and drain regions 13, a gate contact CB, an interlayer insulation layer 29, an etch stopping layer 69, dummy spacers 23 and 24, gate trenches GT1 and GT2, fin recesses FR1 and FR2, active contacts CA2 to CA5, and diffusion break regions SDB1 and SDB2.

The substrate 11 may include a semiconductor material such as silicon (Si) or germanium (Ge), although embodiments are not limited thereto. For example, the substrate 11 may include one or more materials selected from among Si, Ge, silicon germanium (SiGe), gallium phosphide (GaP), gallium arsenide (GaAs), silicon carbide (SiC), silicon germanium carbide (SiGeC), indium arsenide (InAs), and indium phosphide (InP). In an embodiment, the substrate 11 may be a silicon-on-insulator (SOI) substrate.

The active region AR may extend long in the first direction (i.e., X direction) parallel to an upper surface of the substrate 11. The active region AR may be spaced apart from an adjacent active region AR in the second direction (i.e., Y direction) parallel to the upper surface of the substrate 11 and intersecting with the first direction. The active region AR may protrude (i.e., extend above) in a third direction (Z direction) perpendicular to the upper surface of the substrate 11. The active fin F2 may be disposed on the active region AR. The active fin F2 may protrude in a third direction (i.e., Z direction) perpendicular to the upper surface of the substrate 11 on the active region AR.

Each of the active region AR and the active fin F2 may be a portion of the substrate 11 and may include an epitaxial layer grown from the substrate 11. In an embodiment, the active region AR and the active fin F2 may include a semiconductor material. For example, the active region AR and the active fin F2 may include Si or SiGe, although embodiments are not limited thereto.

In an embodiment, the active region AR and the active fin F2 may include the same material as that of the substrate 11. When the substrate 11 includes Si, the active region AR and the active fin F2 may also include Si. A device isolation layer may be formed in the substrate 11 except the active region AR and the active fin F2.

The gate structure G2 may be disposed on the active fin F2. The gate structure G2 may include gate electrodes 17, 19, and 21 and a gate insulation layer 15. A gate spacer 22 may be formed at both (opposite) sidewalls of the gate structure G2 in the first direction. In some embodiments, the gate structure G2 may also include the gate spacer 22.

The gate electrodes 17, 19, and 21 may be configured with three layers. In an embodiment, the gate electrodes 17, 19, and 21 may include a first gate metal layer 17, a second gate metal layer 19, and a third gate metal layer 21.

In an embodiment, the first and second gate metal layers 17 and 19 may include at least one of TIN, WN, TiAl, TiAlC, TiAlN, TaN, TiC, TaC, TaCN, TaSiN, or a combination thereof. In an embodiment, the third gate metal layer 21 may include at least one of tungsten (W), aluminum (Al), cobalt (Co), titanium (Ti), tantalum (Ta), polysilicon (poly-Si), SiGe, or a metal alloy, although embodiments are not limited thereto.

The gate insulation layer 15 may be between the gate electrodes 17, 19, and 21 and the active fin F2. The gate insulation layer 15 may extend in the second direction along a profile of the active fin F2. The gate insulation layer 15 may be formed to extend in the third direction along a side surface of each of the gate electrodes 17, 19, and 21.

For example, the gate electrodes 17, 19, and 21 and the gate insulation layer 15 may be formed through a gate replacement process or a gate last process. The gate insulation layer 15 may include a high dielectric constant (high-k) dielectric material having a dielectric constant which is higher than that of silicon oxide. For example, the gate insulation layer 15 may include hafnium oxide (HfO₂), zirconium oxide (ZrO₂), lanthanum oxide (LaO), aluminum oxide (Al₂O₃), or tantalum oxide (Ta₂O₅).

The gate spacer 22 may be disposed at opposite sides of the gate insulation layer 15, in the first direction, and the gate electrodes 17, 19, and 21 extending in the second direction. The gate spacer 22 may contact both side surfaces of the gate insulation layer 15. The gate spacer 22 may include silicon nitride, although embodiments are not limited thereto. For example, the gate spacer 22 may include at least one of silicon nitride, silicon oxynitride, silicon oxide, silicon oxide carbide nitride, and/or a combination thereof.

The gate contact CB may be disposed on the gate structure G2 on the active fin F2. The gate contact CB may be electrically connected with the gate structure G2. The gate contact CB may be configured as a metal layer 31. The metal layer 31 may include W, Al, or copper (Cu).

The source and drain regions 13 may be disposed at opposite sides of the gate structure G2 in the first direction. The source and drain regions 13 may be disposed in the active fin F2. The source and drain regions 13 may be disposed in a region where a portion of the active fin F2 is etched. In an embodiment, the source and drain regions 13 may include Si, SiGe, SiC, or SiP. In an embodiment, the source and drain regions 13 may be formed through epitaxial growth.

The interlayer insulation layer 29 may be disposed on the source and drain regions 13. The interlayer insulation layer 29 may be formed to contact an outer sidewall of the gate spacer 22. The interlayer insulation layer 29 may electrically insulate the gate structures G1 and G2 (see FIG. 1) from each other. The interlayer insulation layer 29 may electrically insulate the gate structure G2 from the active contacts CA3 and CA4. In an embodiment, the interlayer insulation layer 29 may include at least one of silicon oxide, silicon nitride, silicon oxynitride, and a low-k dielectric material.

The interlayer insulation layer 29 may include a first interlayer insulation layer 25 formed on the gate spacer 22 and a second interlayer insulation layer 27 formed on the first interlayer insulation layer 25. In an embodiment, the first interlayer insulation layer 25 may include silicon oxide or a low-k dielectric material, and the second interlayer insulation layer 27 may include silicon nitride or silicon oxynitride, although embodiments are not limited thereto.

The etch stopping layer 69 may be on the gate structure G2, the interlayer insulation layer 29, the gate contact CB, and the active contacts CA2 to CA4. The etch stopping layer 69 may cover an upper surface of the gate structure G2 and an upper surface of the interlayer insulation layer 29. For example, the etch stopping layer 69 may include silicon nitride. The term “cover” (or “covering,” or like terms), as may be used herein, is intended to broadly refer to an element, structure or layer that is on or over another element, structure or layer, either directly or with one or more other intervening elements, structures or layers therebetween.

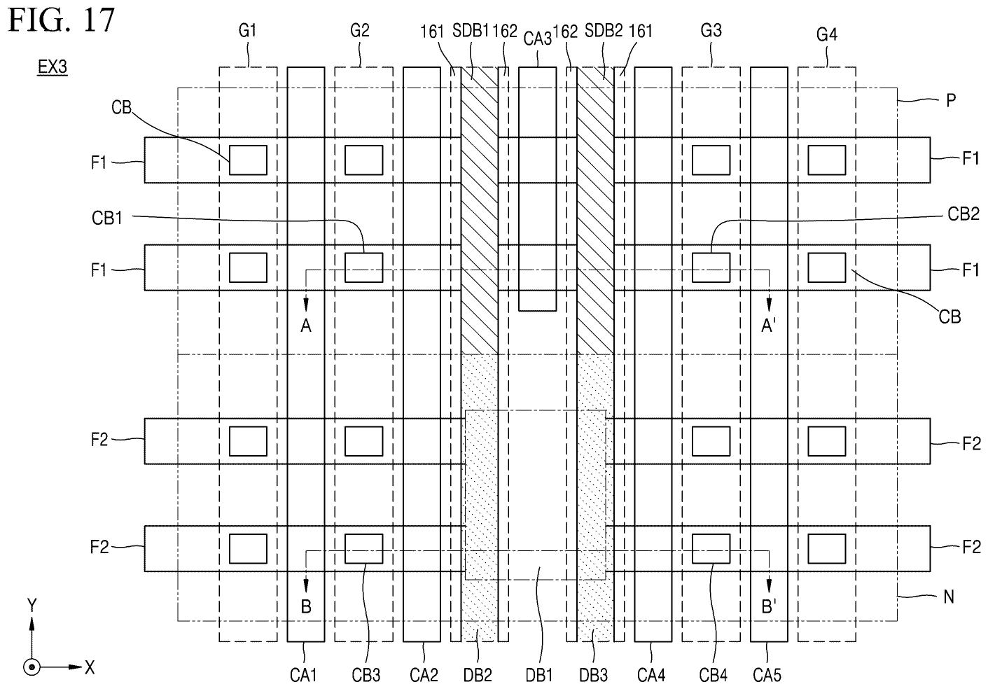

The dummy spacers 23 and 24 may be a pair of spacers where inner surfaces thereof face each other. For example, the dummy spacers 23 and 24 may include an outer spacer 23 and an inner spacer 24. Outer sidewalls of dummy spacers 161 and 162 may contact source and drain regions 120 and an interlayer insulation layer 130 (see FIGS. 17-24B).

The active contacts CA2 to CA5 may be disposed on the source and drain regions 13 on the active fin F2. The active contacts CA2 to CA5 may be electrically connected with the source and drain regions 13. The active contacts CA2 to CA5 may pass through the interlayer insulation layer 29 and may contact the source and drain regions 13 or the active fin F2. The active contacts CA2 to CA5 may be configured as a metal layer 33. The metal layer 33 may include W, Al, or Cu, although embodiments are not limited thereto.

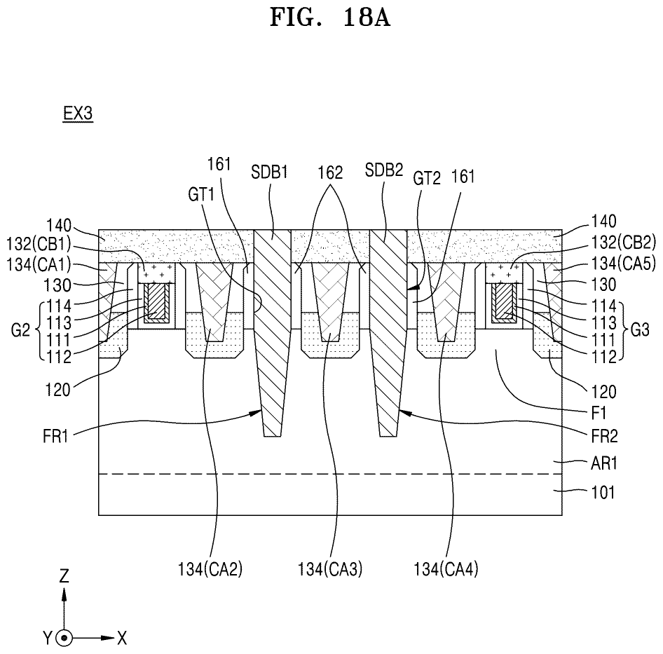

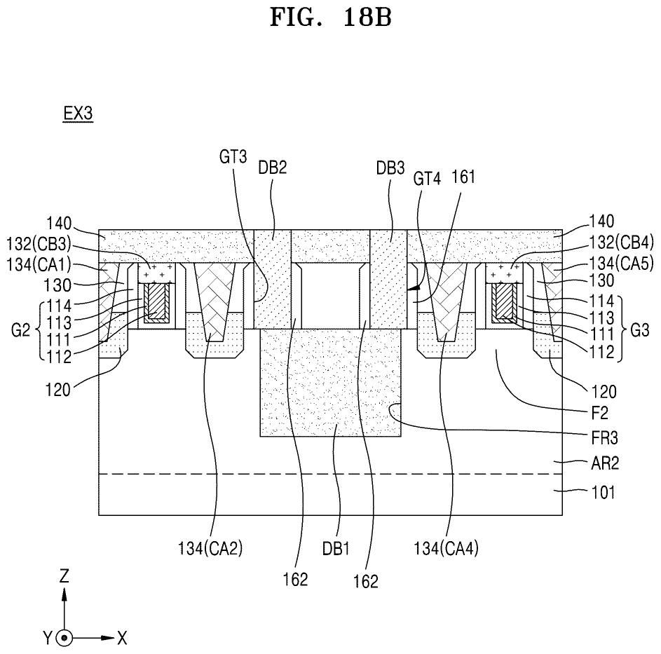

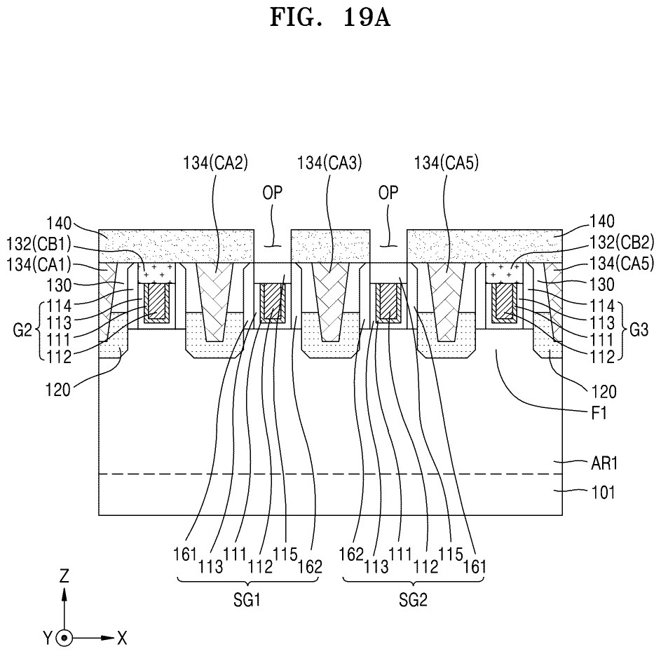

The first and second gate trenches GT1 and GT2 may be between the active contact CA2 and the active contact CA3 and between the active contact CA4 and the active contact CA5. In an embodiment, the first and second gate trenches GT1 and GT2 may be arranged apart from each other in the first direction. The first and second gate trenches GT1 and GT2 may extend long in the second direction along the dummy spacers 161 and 162 (see, e.g., FIG. 18A). Each of the first and second gate trenches GT1 and GT2 may be a portion passing through the etch stopping layer 69 and the interlayer insulation layer 29.

The fin recesses FR1 and FR2 may include a first fin recess FR1 and a second fin recess FR2. The first fin recess FR1 may be between the active contacts CA2 and CA3. The second fin recess FR2 may be between the active contacts CA3 and CA4. In an embodiment, the first and second fin recesses FR1 and FR2 may be arranged apart from each other in the first direction and the second direction. For example, the first and second fin recesses FR1 and FR2 may be arranged apart from the active fin F2 in the first direction. Sidewalls of the first and second fin recesses FR1 and FR2 may contact a short side of the active fin F2.

The sidewalls of the first and second fin recesses FR1 and FR2 may be defined by the active fin F2. The first and second fin recesses FR1 and FR2 may expose the active fin F2. The term “expose” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The first and second fin recesses FR1 and FR2 may be under the first and second gate trenches GT1 and GT2. The first and second fin recesses FR1 and FR2 may overlap the first and second gate trenches GT1 and GT2 in terms of a plane parallel to the first and second directions. Specifically, the term “overlap” (or “overlapping,” or like terms), as may be used herein, is intended to broadly refer to a first element that intersects with at least a portion of a second element in the vertical direction (i.e., the third (Z) direction), but does not require that the first and second elements be completely aligned with one another in a horizontal plane (i.e., in the first (X) direction and/or the second (Y) direction).

The first and second fin recesses FR1 and FR2 may long extend downward (i.e., in the Z direction) from the first and second gate trenches GT1 and GT2 and may cut the active fin F2. The first and second fin recesses FR1 and FR2 may be merged with the first and second gate trenches GT1 and GT2 to form a one-body trench space.

The diffusion break regions SDB1 and SDB2 may be in the first and second gate trenches GT1 and GT2 and the first and second fin recesses FR1 and FR2. The diffusion break regions SDB1 and SDB2 may be formed between the active contacts CA2 and CA3 and between the active contacts CA4 and CA5. The diffusion break regions SDB1 and SDB2 may prevent the diffusion of impurities included in the active region AR or the source and drain regions 13.

The diffusion break regions SDB1 and SDB2 may be single diffusion break regions configured as one insulation layer. The diffusion break regions SDB1 and SDB2 may include a first single diffusion break region SDB1 in the first gate trench GT1 and the first fin recess FR1 and a second single diffusion break region SDB2 in the second gate trench GT2 and the second fin recess FR2.

The diffusion break regions SDB1 and SDB2 may fill the first and second gate trenches GT1 and GT2 and the first and second fin recesses FR1 and FR2. The term “fill” (or “filling,” or like terms), as may be used herein, is intended to refer broadly to either completely filling a defined space (e.g., the first and second gate trenches GT1 and GT2) or partially filling the defined space; that is, the defined space need not be entirely filled but may, for example, be partially filled or have voids or other spaces throughout, unless specified otherwise. The single diffusion break regions SDB1 and SDB2 may contact the active fin F2 and the active region AR each exposed by the first and second fin recesses FR1 and FR2.

The diffusion break regions SDB1 and SDB2 may contact the dummy spacers 23 and 24. The diffusion break regions SDB1 and SDB2 may extend in the third direction from the first and second gate trenches GT1 and GT2, and upper portions of the diffusion break regions SDB1 and SDB2 may be between adjacent etch stopping layers 140 (see FIGS. 18A-24B). The diffusion break regions SDB1 and SDB2 may include the same material as that of the etch stopping layer 140. The diffusion break regions SDB1 and SDB2 may be provided as one body with the etch stopping layer 140. In an embodiment, the diffusion break regions SDB1 and SDB2 may include silicon nitride.

In the integrated circuit semiconductor device EX1 according to an embodiment, the etch stopping layer 69 may be on the plurality of active contacts CA1 to CA5 and the plurality of gate contacts CB. In the integrated circuit semiconductor device EX1, the diffusion break regions SDB1 and SDB2 may be in the first and second gate trenches GT1 and GT2 and the first and second fin recesses FR1 and FR2 between the plurality of active contacts CA1 to CA5. The diffusion break regions SDB1 and SDB2 may be electrically disconnected from each other by the dummy spacers 23 and 24 and the interlayer insulation layer 29.

Accordingly, in the integrated circuit semiconductor device EX1 according to an embodiment, the active contacts CA1 to CA5 and the gate contacts CB may be reliably disposed without being affected by the diffusion break regions SDB1 and SDB2.

Furthermore, in the integrated circuit semiconductor device EX1 according to an embodiment, as described below, the active contacts CA1 to CA5 and the gate contacts CB may be formed, and then, the diffusion break regions SDB1 and SDB2 may be formed, thereby preventing the occurrence of a void in the diffusion break regions SDB1 and SDB2.

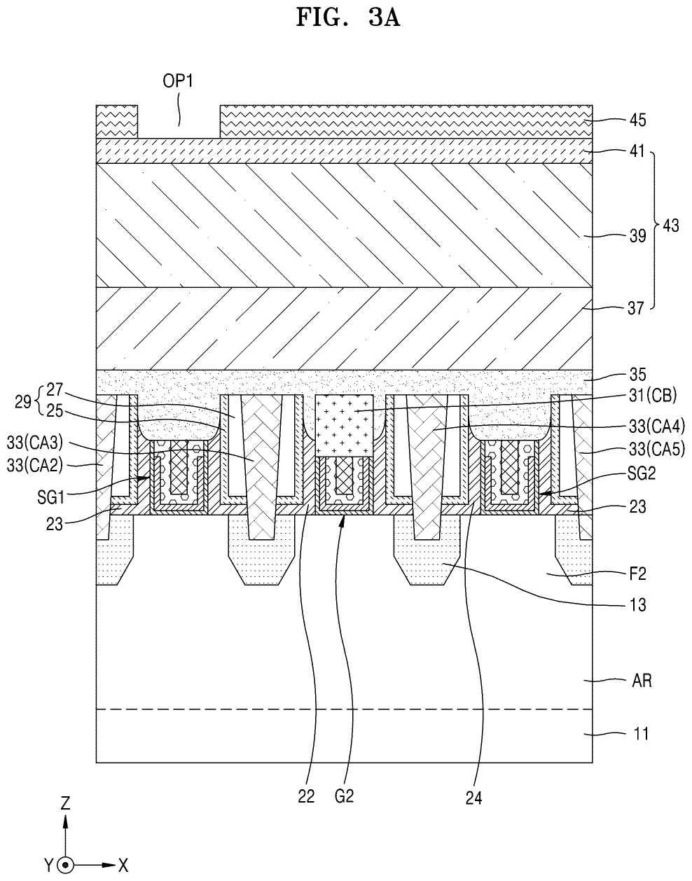

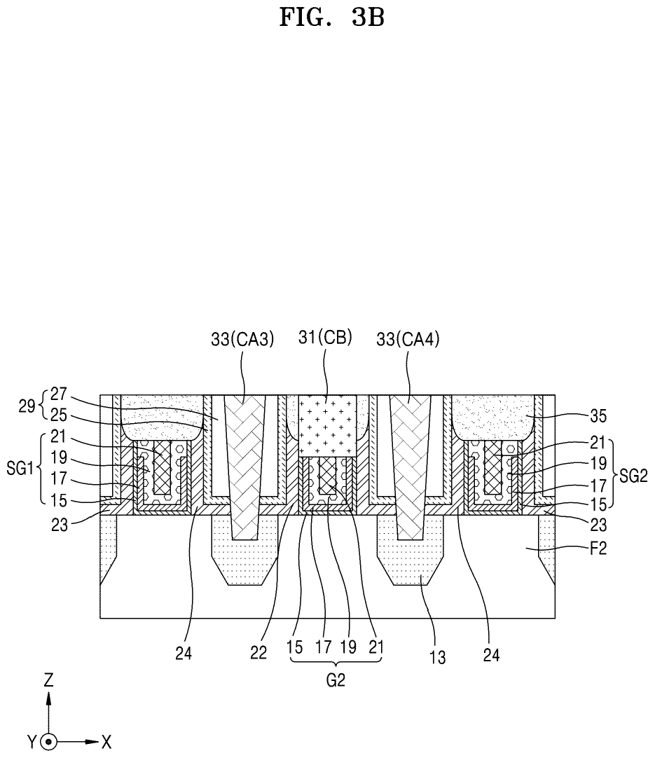

FIGS. 3A to 11 are cross-sectional views depicting intermediate processes in an example method of manufacturing the integrated circuit semiconductor device EX1 of FIGS. 2A and 2B. In FIGS. 3A to 11, like reference numerals refer to like elements. In FIGS. 3A to 11, for convenience of description, descriptions given above with reference to FIGS. 1 to 2B will be briefly given or are omitted.

Referring to FIGS. 3A and 3B, FIG. 3B is a partial enlarged view of FIG. 3A. Processes up to a gate replacement process from a process of forming an active fin F2 on a substrate 11 may be completed. For example, an active region AR and an active fin F2 may be formed on the substrate 11. The active region AR and the active fin F2 may be defined by a device isolation layer.

A gate structure G2, sacrificial gate structures SG1 and SG2, source and drain regions 13, a gate spacer 22, dummy spacers 23 and 24, and an interlayer insulation layer 29 may be formed on the active fin F2.

The sacrificial gate structures SG1 and SG2 may be disposed at opposing sides (in the X direction) of the gate structure G2. The sacrificial gate structures SG1 and SG2 may include a first sacrificial gate structure SG1 and a second sacrificial gate structure SG2.

The gate structure G2 and the sacrificial gate structures SG1 and SG2 may include gate electrodes 17, 19, and 21 and a gate insulation layer 15. The gate spacer 22 may be formed at opposing sidewalls of the gate structure G2. The dummy spacers 23 and 24 may be formed at opposing sidewalls of the sacrificial gate structures SG1 and SG2.

Subsequently, a gate contact CB contacting the gate structure G2 and active contacts CA2 to CA5 contacting the source and drain regions 13 may be formed. The gate contact CB may be formed on the gate structure G2. The gate contact CB may include a metal layer 31, and for example, may include W, Al, or Cu, although embodiments are not limited thereto. The active contacts CA2 to CA5 may be formed on the source and drain regions 13 on the active fin F2. The active contacts CA2 to CA5 may include a metal layer 33, and for example, may include W, Al, or Cu, although embodiments are not limited thereto.

Surfaces of the gate contact CB and the active contacts CA2 to CA5 may include the same surface. The active contacts CA2 to CA5 may be formed in the interlayer insulation layer 29, the gate spacer 22, and the dummy spacers 23 and 24. Upper surfaces of the gate structure G2 and the sacrificial gate structures SG1 and SG2 may be disposed at a level which is lower than upper surfaces of the gate contact CB and the active contacts CA2 to CA5, relative to the upper surface of the substrate 11 as a reference layer.

An etch stopping material layer 35 may be formed on the gate structure G2, the sacrificial gate structures SG1 and SG2, the gate contact CB, the active contacts CA2 to CA5, and the interlayer insulation layer 130 (see, e.g., FIGS. 18A-24B). The etch stopping material layer 35 may include silicon nitride.

A first mask layer 43 may be formed on the etch stopping material layer 35. In an embodiment, the first mask layer 43 may be configured with a plurality of material layers. In an embodiment, the first mask layer 43 may include a first sub mask layer 37, a second sub mask layer 39 formed on the first sub mask layer 37, and a third sub mask layer 41 formed on the second sub mask layer 39. The first sub mask layer 37 may be configured as a silicon oxide layer. The second sub mask layer 39 may be configured as a spin on hard (SOH) mask layer. The third sub mask layer 41 may be configured as a silicon nitride layer. The SOH layer may denote a hydrocarbon compound or a material including derivatives thereof.

A photoresist pattern 45 including a first open region OP1 may be formed on the first mask layer 43 on (i.e., over or vertically overlapping) the first sacrificial gate structure SG1. The photoresist pattern 45 may be formed by using a photolithography process.

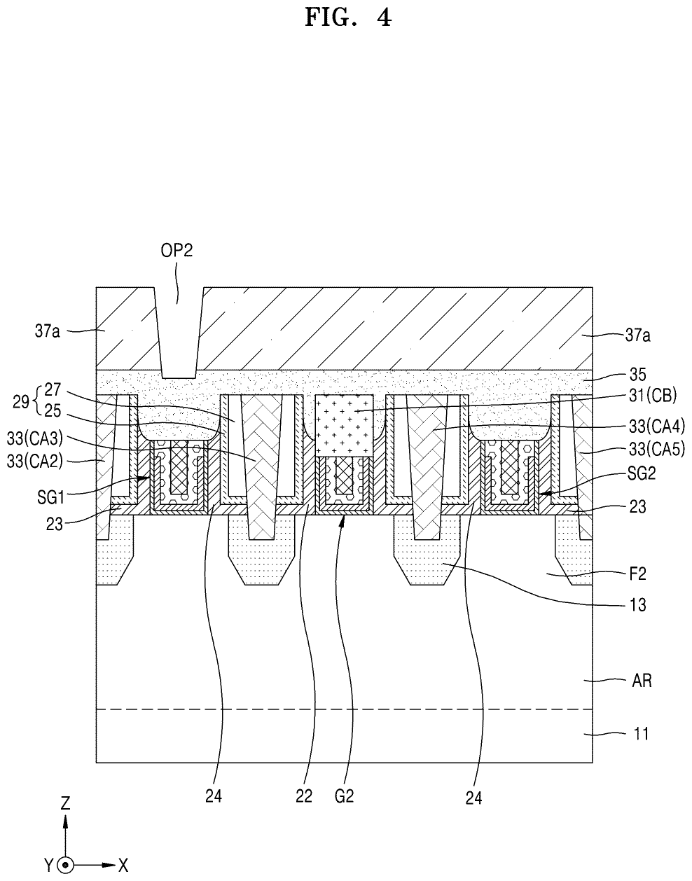

Referring to FIG. 4, the first mask layer 43 may be etched by using the photoresist pattern 45 including the first open region OP1 (see FIG. 3A) as an etch mask. Therefore, a first mask pattern 37a including a second open region OP2 may be formed on the first sacrificial gate structure SG1. The first mask pattern 37a may be a first sub mask pattern.

In a case where the first mask layer 43 is etched by using the photoresist pattern 45 (see FIG. 3A) as an etch mask, the second sub mask layer 39 (see FIG. 3A) and the third sub mask layer 41 (see FIG. 3A) may be removed. In a case where the first mask layer 43 (see FIG. 3A) is etched by using the photoresist pattern 45 (see FIG. 3A) as an etch mask, a portion of a surface of the etch stopping material layer 35 may be etched (through the open region OP2).

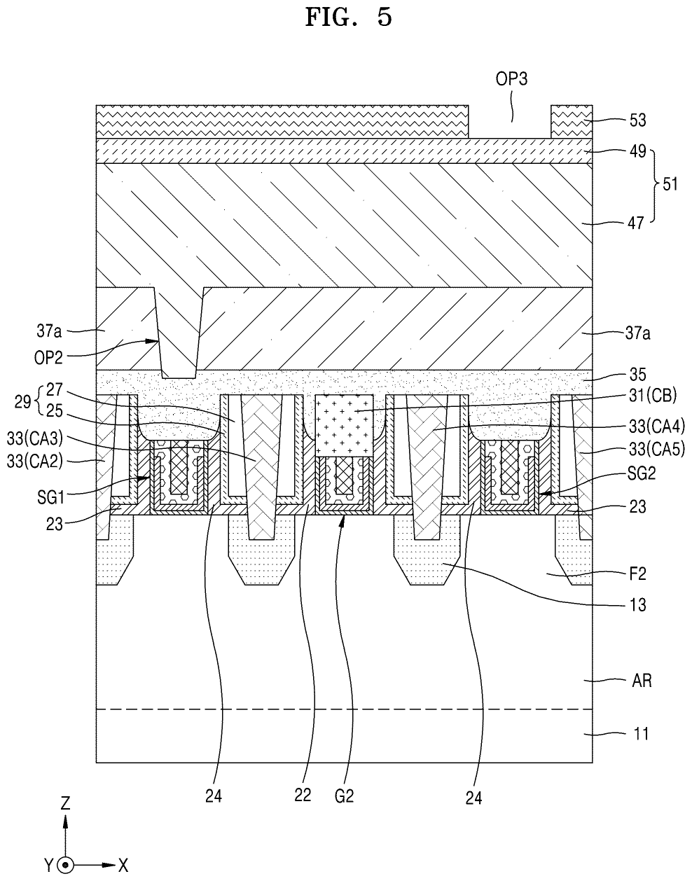

Referring to FIG. 5, a second mask layer 51 may be formed on the first mask pattern 37a including the second open region OP2. In an embodiment, the second mask layer 51 may be configured with a plurality of material layers. In an embodiment, the second mask layer 51 may include a fourth sub mask layer 47, and a fifth sub mask layer 49. The fourth sub mask layer 47 may be configured as an SOH mask layer. The fifth sub mask layer 49 may be configured as a silicon nitride layer.

A photoresist pattern 53 including a third open region OP3 may be formed on the second mask layer 51 on (i.e., vertically overlapping) the second sacrificial gate structure SG2. The photoresist pattern 53 may be formed by using a photolithography process.

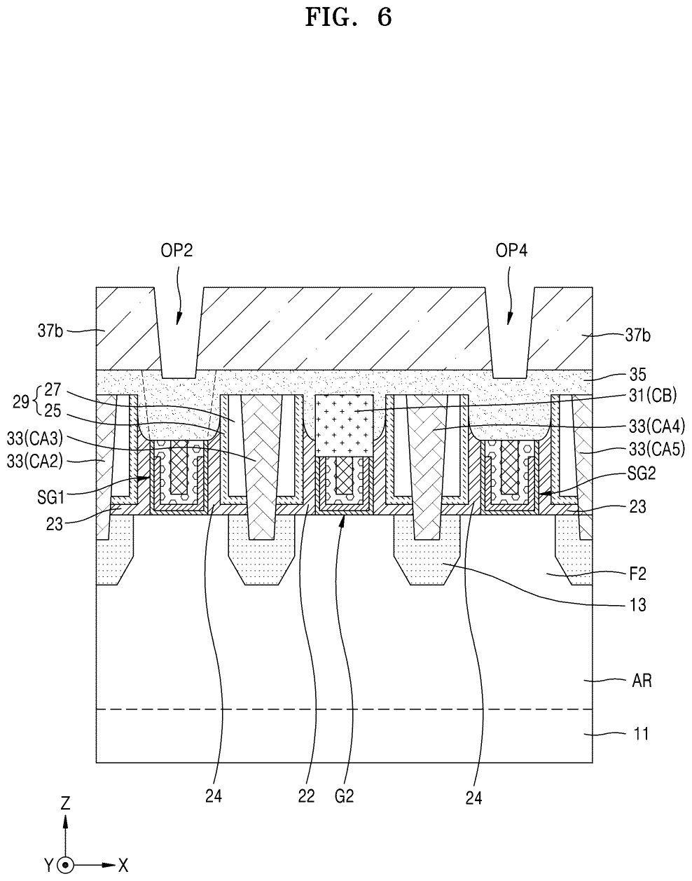

Referring to FIG. 6, the second mask layer 51 (see FIG. 5) may be etched by using the photoresist pattern 53 including the third open region OP3 as an etch mask, and thus, a second mask pattern 37b including a fourth open region OP4 may be formed on the second sacrificial gate structure SG2. Through such a process, the second open region OP2 may be provided on the first sacrificial gate structure SG1, in the second mask pattern 37b.

When the second mask layer 51 (see FIG. 5) is etched by using the photoresist pattern 53 (see FIG. 5) as an etch mask, the second mask layer 51 (see FIG. 5) may be removed. When the second mask layer 51 (see FIG. 5) is etched by using the photoresist pattern 53 (see FIG. 5) as an etch mask, a portion of a surface of the etch stopping material layer 35 may be etched (through the open region OP4).

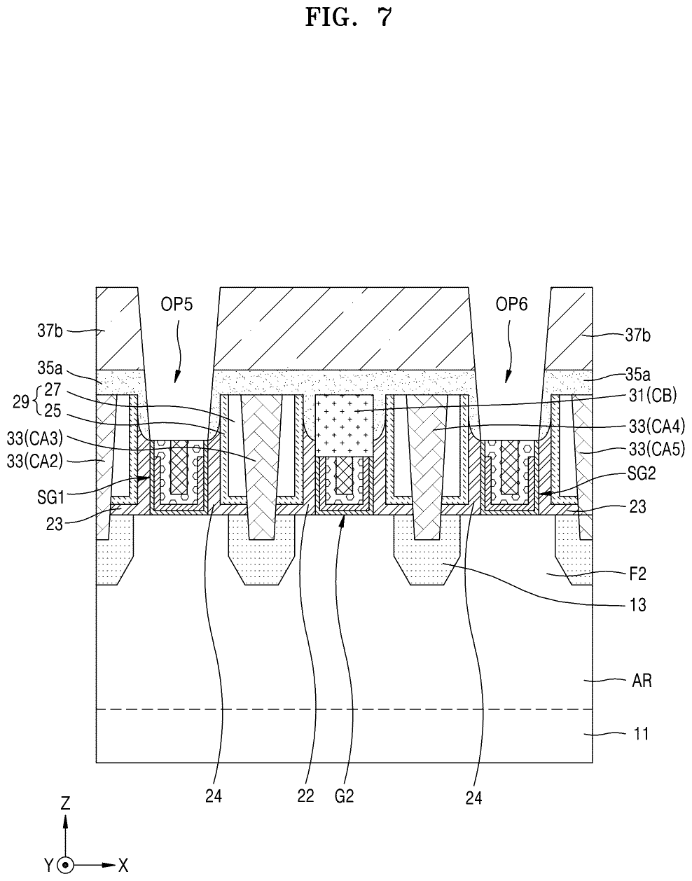

Referring to FIG. 7, an etch stopping material layer 35 may be etched by using the second mask pattern 37b including the second and fourth open regions OP2 and OP4 as an etch mask. Therefore, a fifth open region OP5 and a sixth open region OP6 may be respectively formed on the first sacrificial gate structure SG1 and the second sacrificial gate structure SG2.

As the fifth open region OP5 and the sixth open region OP6 are formed, the etch stopping material layer 35 may be changed to an etch stopping material layer pattern 35a. In other words, through the process described above, the etch stopping material layer pattern 35a including the fifth open region OP5 and the sixth open region OP6 may be formed. The fifth open region OP5 and the sixth open region OP6 may expose upper surfaces of the first sacrificial gate structure SG1 and the second sacrificial gate structure SG2, respectively.

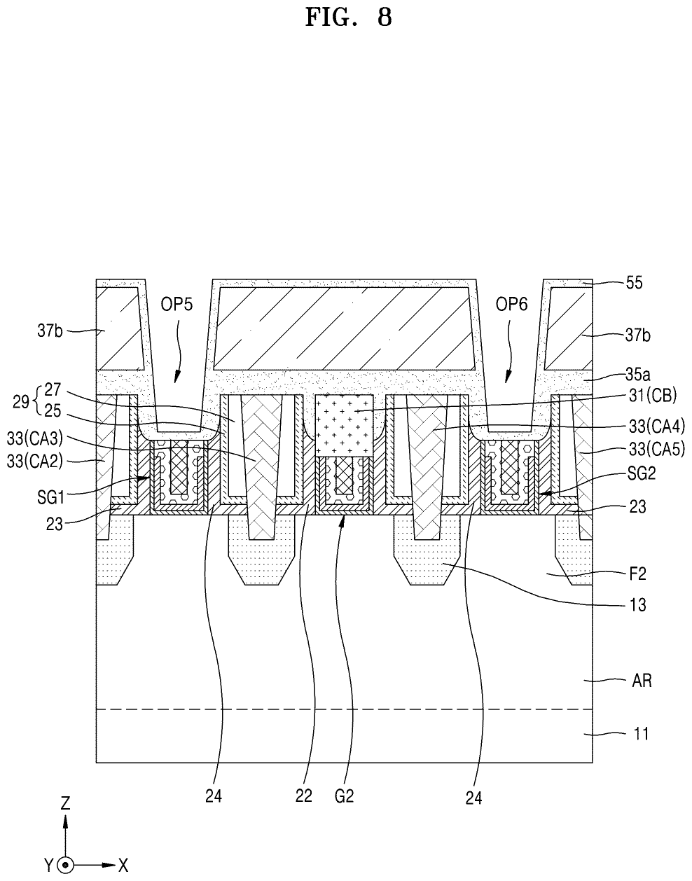

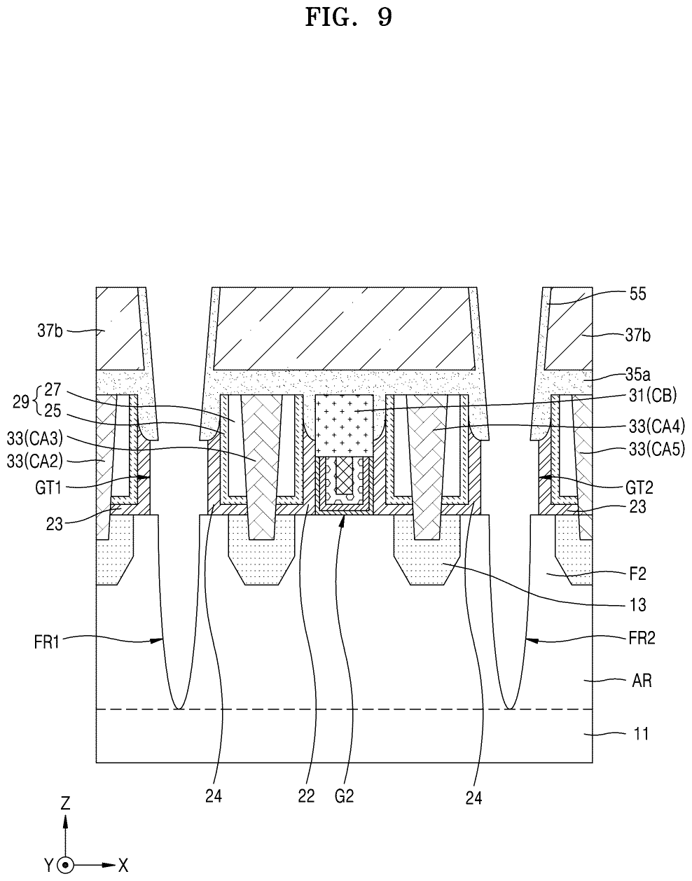

Referring to FIG. 8, a liner material layer 55 may be conformally formed on inner walls of the fifth open region OP5 and the sixth open region OP6. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The liner material layer 55 may not be formed depending on the case. In an embodiment, the liner material layer 55 may include silicon nitride. The liner material layer 55 may be formed on the dummy spacers 23 and 24 and the upper surfaces of the first sacrificial gate structure SG1 and the second sacrificial gate structure SG2.

Referring to FIG. 9, first and second gate trenches GT1 and GT2 may be formed by etching the first and second sacrificial gate structures SG1 and SG2 through the fifth open region OP5 and the sixth open region OP6 (see FIG. 8). Sidewalls of the dummy spacers 23 and 24 and an upper portion of the active fin F2 may be exposed through the first and second gate trenches GT1 and GT2. The first and second sacrificial gate structures SG1 and SG2 may be etched through anisotropic etching and/or isotropic etching.

Subsequently, first and second fin recesses FR1 and FR2 may be formed by etching the active fin F2 where the upper portion is exposed through the first and second gate trenches GT1 and GT2. The first and second fin recesses FR1 and FR2 may be formed to extend downward (i.e., in the Z direction) from the first and second gate trenches GT1 and GT2. The first and second fin recesses FR1 and FR2 may be merged with the first and second gate trenches GT1 and GT2 to form a one-body connected space; that is, sidewalls of the first fin recess FR1 and the first gate trench GT1 may be contiguous with each other, and likewise sidewalls of the second fin recess FR2 and the second gate trench GT2 may be contiguous with each other.

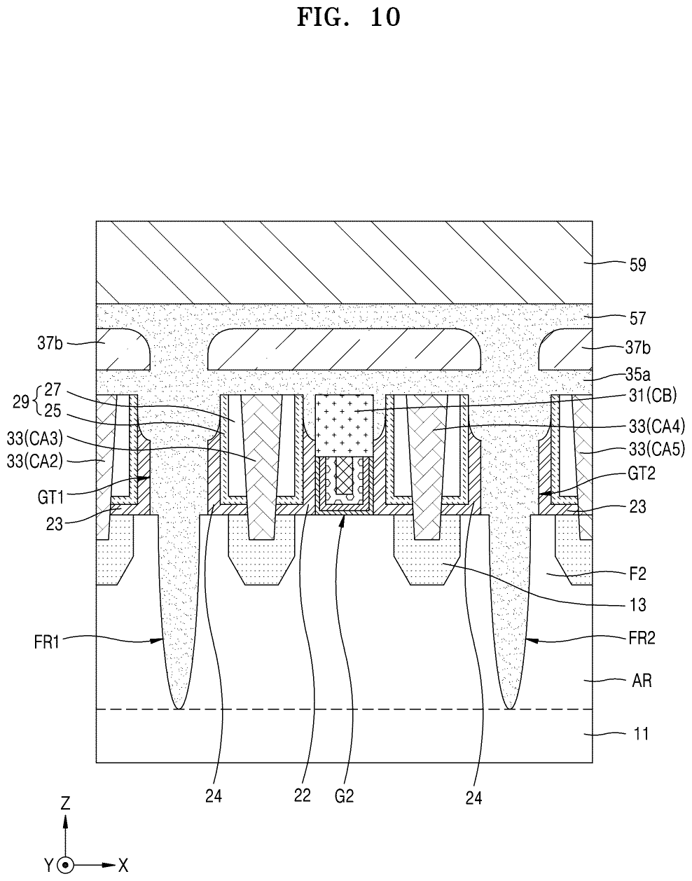

Referring to FIG. 10, diffusion break material layers 57 and 59 may be formed on the etch stopping material layer 35a and the second mask pattern 37b while filling inner portions of the first and second fin recesses FR1 and FR2 and the first and second gate trenches GT1 and GT2. The diffusion break material layers 57 and 59 may completely fill the first and second fin recesses FR1 and FR2 and the first and second gate trenches GT1 and GT2 without a void.

The diffusion break material layers 57 and 59 may be configured as a plurality of layers. The diffusion break material layers 57 and 59 may include a first diffusion break material layer 57 and a second diffusion break material layer 59. The diffusion break material layers 57 and 59 may include silicon nitride. An upper shape of the second mask pattern 37b may be rounded in forming the diffusion break material layers 57 and 59.

The etch stopping material layer pattern 35a and the diffusion break material layers 57 and 59 may include the same material. Therefore, in FIG. 10, a boundary between the diffusion break material layers 57 and 59 and the etch stopping material layer pattern 35a is not illustrated for convenience.

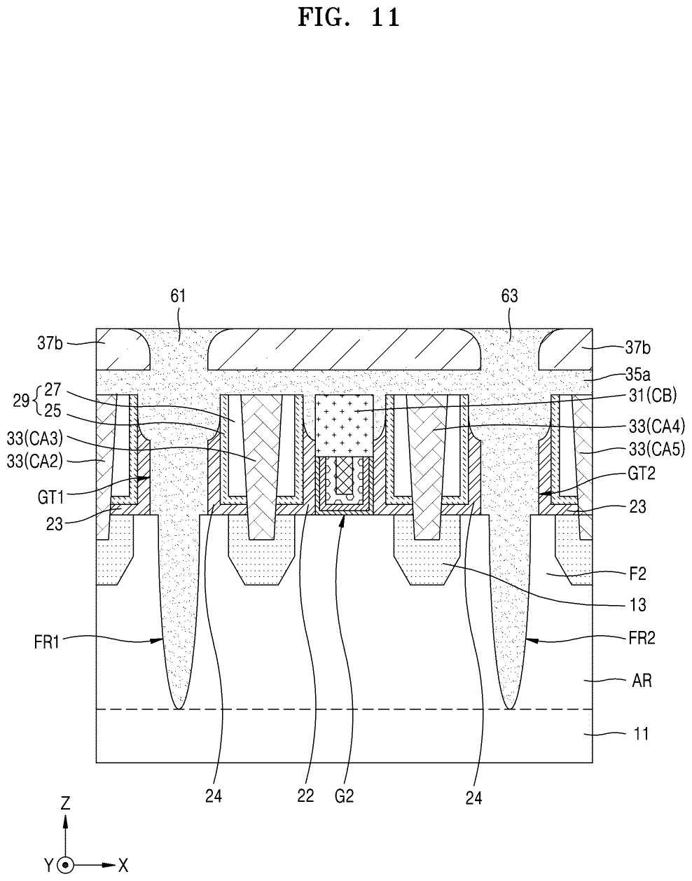

Referring to FIG. 11, the second diffusion break material layer 59 and the first diffusion break material layer 57 may be primarily planarized by using the second mask pattern 37b as an etch stop point. The primary planarization may be performed by using a chemical mechanical polishing (CMP) process.

A first diffusion break material pattern 61 may be formed in the first fin recess FR1 and the first gate trench GT1 through a primary planarization process. A second diffusion break material pattern 63 may be formed in the second fin recess FR2 and the second gate trench GT2 through the primary planarization process. After planarization, an upper surface of the first diffusion break material pattern 61, an upper surface of the second diffusion break material pattern 63, and an upper surface of the second mask pattern 37b may be at the same level relative to the upper surface of the substrate 11 (i.e., coplanar).

Subsequently, as illustrated in FIG. 2A, the first diffusion break material pattern 61 and the second diffusion break material pattern 63 may be secondarily planarized by using an upper surface of the etch stopping material layer pattern 35a as an etch stop point. The secondary planarization may be performed by using a CMP process.

Therefore, the first diffusion break material pattern 61 may be further etched, and thus, a diffusion break region SDB1 is buried in the first fin recess FR1 and the first gate trench GT1. The second diffusion break material pattern 63 may be further etched, and thus, a diffusion break region SDB2 is buried in the second fin recess FR2 and the second gate trench GT2.

As described above, the diffusion break regions SDB1 and SDB2 may be void-free diffusion break regions where a void is not formed. Furthermore, a portion of a surface of the etch stopping material layer pattern 35a may be etched, and thus, an etch stopping layer 69 (see FIG. 2A) may be formed on the gate structure G2 and the interlayer insulation layer 29.

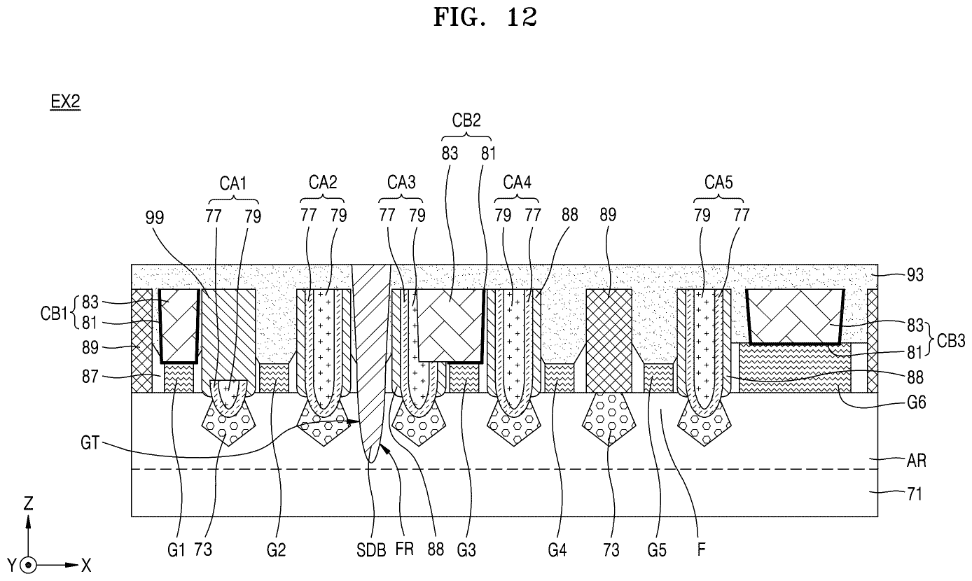

FIG. 12 is a cross-sectional view of a partial region of an integrated circuit semiconductor device EX2 according to an embodiment.

In detail, the integrated circuit semiconductor device EX2 may include a substrate 71, an active region AR, an active fin F, gate structures G1 to G6, source and drain regions 73, gate contacts CB1 to CB3, an interlayer insulation layer 87, an etch stopping layer 93, dummy spacers 88, a gate trench GT, a fin recess FR, active contacts CA1 to CA5, and a diffusion break region SDB.

The substrate 71 may include a semiconductor material such as Si or Ge, although embodiments are not limited thereto. For example, the substrate 71 may include one or more materials selected from among Si, Ge, SiGe, GaP, GaAs, SiC, SiGeC, InAs, and InP. In an embodiment, the substrate 71 may be an SOI substrate.

The active region AR may extend long in a first direction (an X direction) parallel to an upper surface of the substrate 71. The active region AR may be apart from an adjacent active region AR in a second direction (Y direction) parallel to the upper surface of the substrate 71 and intersecting with the first direction. The active region AR may protrude in a third direction (a Z direction) perpendicular to the upper surface of the substrate 71. The active fin F may be on the active region AR. The active fin F may protrude in the third direction on the active region AR.

Each of the active region AR and the active fin F may be a portion of the substrate 71 and may include an epitaxial layer grown from the substrate 71. In an embodiment, the active region AR and the active fin F may include a semiconductor material. For example, the active region AR and the active fin F may include Si or SiGe.

In an embodiment, the active region AR and the active fin F may include the same material as that of the substrate 71. When the substrate 71 includes Si, the active region AR and the active fin F may also include Si. A device isolation layer may be formed in the substrate 71 except the active region AR and the active fin F.

The gate structures G1 to G6 may be on the active fin F. The gate structures G1 to G6 may be arranged apart from one another in the first direction. The gate structures G1 to G6 may each include a gate electrode, a gate insulation layer, and/or a gate spacer.

The gate contacts CB1 to CB3 may be on some of the gate structures G1 to G6 on the active fin F. The gate contacts CB1 to CB3 may have different widths or heights relative to one another. The gate contacts CB1 to CB3 may be electrically connected with the gate structures G1 to G3, respectively. The gate contacts CB1 to CB3 may be configured with a barrier metal layer 81 and a metal layer 83. The barrier metal layer 81 may include Ti or TiN, and the metal layer 83 may include W, Al, or Cu, although embodiments are not limited thereto.

The source and drain regions 73 may be disposed at both (opposite) sides of the gate structures G1 to G6. The source and drain regions 73 may be spaced apart from each other in the first direction. The source and drain regions 73 may be in the active fin F. The source and drain regions 73 may be in a region where a portion of the active fin F is etched.

In an embodiment, the source and drain regions 73 may include Si, SiGe, SiC, or SiP, although embodiments are not limited thereto. In an embodiment, the source and drain regions 73 may be formed through epitaxial growth. An active contact may not be formed and an insulation layer 89 may be formed on some of the source and drain regions 73. The insulation layer 89 may include a silicon oxide layer or a silicon nitride layer, although embodiments are not limited thereto.

The interlayer insulation layer 87 may be formed to contact an outer sidewall of each of the gate structures G1 to G6. The interlayer insulation layer 87 may be formed to contact the dummy spacers 88 on outer sidewalls of the active contacts CA1 to CA5. In an embodiment, the interlayer insulation layer 87 may include at least one of silicon oxide, silicon nitride, silicon oxynitride, and a low-k dielectric material.

The etch stopping layer 93 may be on the active contacts CA1 to CA5, the gate contacts CB1 to CB3, and some of the gate structures G1 to G6. A lower surface of the etch stopping layer 93 may be at a level which is lower than an upper surface of each of the active contacts CA1 to CA5 and the gate contacts CB1 to CB3, relative to the upper surface of the substrate 71 as a reference layer. For example, the etch stopping layer 93 may include silicon nitride.

The dummy spacers 88 may be formed on some sidewalls of the active contacts CA1 to CA5. The dummy spacers 88 may be formed on some sidewalls of the active contacts CA2 to CA5. Outer sidewalls of the dummy spacers 88 may contact the etch stopping layer 93.

The active contacts CA1 to CA5 may be on the source and drain regions 73 on the active fin F. The active contacts CA1 to CA5 may have different widths or heights with respect to each other. An insulation layer 99 having the same height as that of each of the gate contacts CB1 to CB3 may be formed on the active contact CA1. The insulation layer 99 may include a silicon oxide layer or a silicon nitride layer.

The active contacts CA1 to CA5 may be electrically connected with the source and drain regions 73. The active contacts CA1 to CA5 may include a barrier metal layer 77 and a metal layer 79. The barrier metal layer 77 may include Ti or TiN, and the metal layer 19 may include W, Al, or Cu.

The gate trench GT may be between the second active contact CA2 and the third active contact CA3. The gate trench GT may extend long in the second direction along the dummy spacers 88.

The fin recess FR may be between the active contacts CA2 and CA3. A sidewall of the fin recess FR may be defined by the active fin F. The fin recess FR may expose the active fin F. The fin recess FR may be under the gate trench GT. The fin recess FR may overlap the gate trench GT in terms of a plane.

The fin recess FR may extend long from the gate trench GT and may cut the active fin F. The fin recess FR may be merged with the gate trench GT to form a one-body trench space.

The fin recess FR may be in the gate trench GT and the fin recess FR. The diffusion break region SDB may fill the fin recess FR and the gate trench GT. The diffusion break region SDB may contact the active fin F and the active region AR each exposed by the fin recess FR.

The diffusion break region SDB may contact the interlayer insulation layer 87 and the dummy spacers 88. The diffusion break region SDB may extend in the third direction from the gate trench GT, and an upper portion of the diffusion break region SDB may be between adjacent etch stopping layers 93. The diffusion break region SDB may include the same material as that of the etch stopping layer 93. In an embodiment, the diffusion break region SDB may include silicon nitride.

In the integrated circuit semiconductor device EX2 according to an embodiment, the etch stopping layer 69 (see FIG. 2A) may be on the plurality of active contacts CA1 to CA5 and the plurality of gate contacts CB1 to CB3. For the integrated circuit semiconductor device EX2, the diffusion break region SDB may be disposed in the gate trench GT and the fin recess FR, between some of the active contacts CA1 to CA5. The diffusion break region SDB may be electrically disconnected by the dummy spacers 88 and the interlayer insulation layer 87.

Accordingly, in the integrated circuit semiconductor device EX2 according to an embodiment, the active contacts CA1 to CA5 and the gate contacts CB1 to CB3 may be reliably disposed without being affected by the diffusion break region SDB.

Furthermore, in the integrated circuit semiconductor device EX2 according to an embodiment, as described below, the active contacts CA1 to CA5 and the gate contacts CB1 to CB2 may be formed, and then, the diffusion break region SDB may be formed, thereby preventing the occurrence of a void in the diffusion break region SDB.

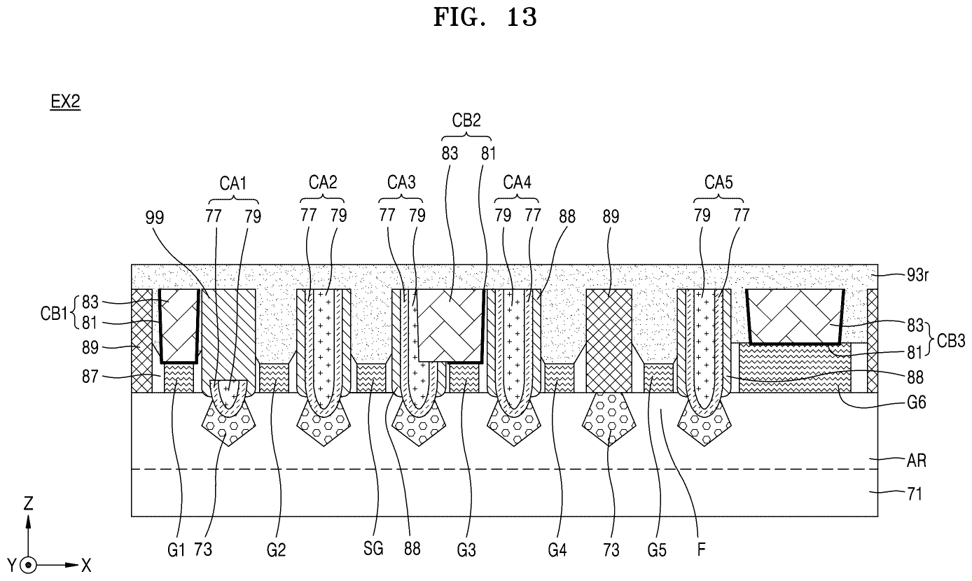

FIGS. 13 to 16 are cross-sectional views depicting intermediate processes in an example method of manufacturing the integrated circuit semiconductor device EX2 of FIG. 12. In FIGS. 13 to 16, like reference numerals refer to like elements. In FIGS. 13 to 16, for convenience of description, descriptions given above with reference to FIG. 12 will be briefly given or are omitted.

Referring to FIG. 13, processes up to a gate replacement process from a process of forming the active fin F on the substrate 71 may be completed. For example, an active region AR and an active fin F may be formed on the substrate 71. The active region AR and the active fin F may be defined by a device isolation layer.

The gate structures G1 to G6, the sacrificial gate structure SG, the source and drain regions 73, the dummy spacers 88, and the interlayer insulation layers 87 may be formed on the active fin F. The sacrificial gate structure SG may be between the gate structures G2 and G3 in the first direction (X direction). The interlayer insulation layer 87 and the dummy spacers 88 may be formed on opposite sidewalls (in the first direction) of the sacrificial gate structure SG.

Subsequently, the gate contacts CB1 to CB3 contacting the gate structures G1, G3, and G6 and the active contacts CA1 to CA5 contacting the source and drain regions 73 may be formed. The gate contacts CB1 to CB3 may be formed on the gate structures G1, G3, and G6. The gate contacts CB1 to CB3 may be configured with a barrier metal layer 81 and a metal layer 83.

The active contacts CA1 to CA5 may be disposed on the source and drain regions 73 on the active fin F. The active contacts CA1 to CA5 may include a barrier metal layer 77 and a metal layer 79.

Surfaces of the gate contacts CB1 to CB3 and the active contacts CA1 to CA5 may include the same surface. The active contacts CA1 to CA5 may be formed in the interlayer insulation layer 87 and the dummy spacers 88.

Upper surfaces of the gate structures G1 to G6 and the sacrificial gate structure SG may be disposed at a level which is lower than upper surfaces of the gate contacts CB1 to CB3 and the active contacts CA1 to CA5, relative to the upper surface of the substrate 71.

An etch stopping material layer 93r may be formed on the gate structures G1 to G6, the sacrificial gate structure SG, the gate contacts CB1 to CB3, the active contacts CA1 to CA5, the interlayer insulation layer 87, the dummy spacers 88, and the insulating layer 89. The etch stopping material layer 93r may include silicon nitride.

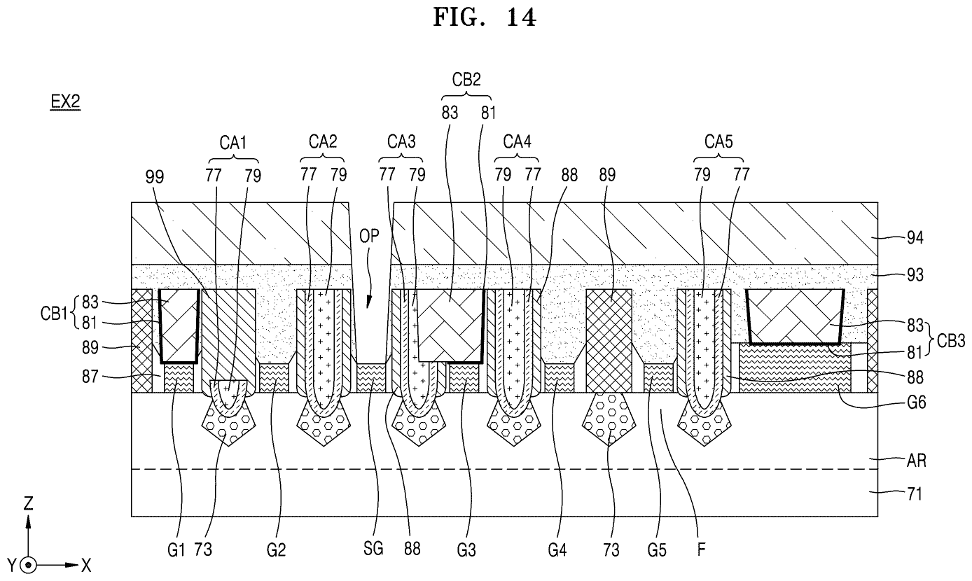

Referring to FIG. 14, a mask pattern 94 including an open region OP may be formed on the etch stopping material layer 93r (see FIG. 13). The mask pattern 94 including the open region OP may be formed by using a photolithography process. The mask pattern 94 may include a silicon oxide layer. Subsequently, an etch stopping layer 93 exposing an upper surface of the sacrificial gate structure SG may be formed by etching the etch stopping material layer 93r with the mask pattern 94 as an etch mask. The open region OP exposing the upper surface of the sacrificial gate structure SG may be formed in the etch stopping layer 93.

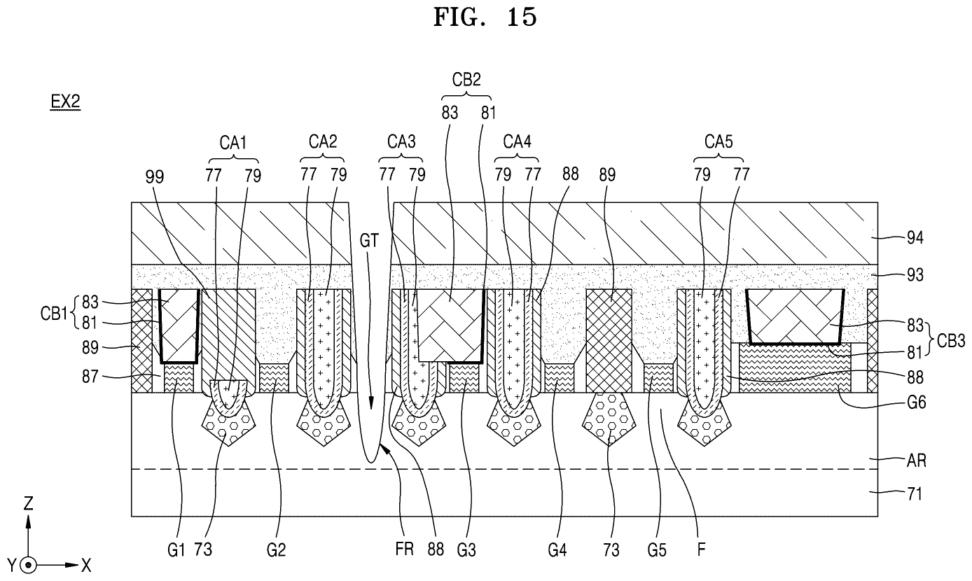

Referring to FIG. 15, a gate trench GT may be formed by etching the sacrificial gate structure SG through the open region OP. A sidewall of the interlayer insulation 87 or the dummy spacers 88 and an upper portion of the active fin F may be exposed through the gate trench GT. The first and second sacrificial gate structure SG may be etched through anisotropic etching and/or isotropic etching.

Subsequently, a fin recess FR may be formed by etching the active fin F where an upper portion is exposed through the gate trench GT. The fin recess FR may extend downward from the gate trench GT. The fin recess FR may be merged with the gate trench GT to form a space connected as one body; that is, sidewalls of the fin recess FR may be contiguous with sidewalls of the gate trench GT.

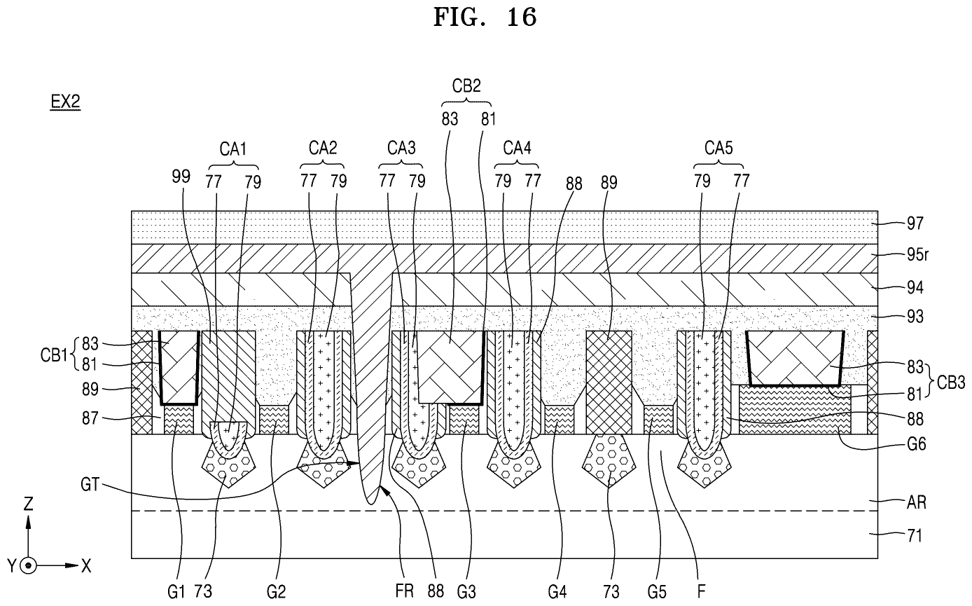

Referring to FIG. 16, diffusion break material layers 95r and 97 may be formed on the etch stopping layer 93 and the mask pattern 94 while filling inner portions of the fin recess FR and the gate trench GT. The diffusion break material layers 95r and 97 may completely fill the fin recess FR and the gate trench GT without a void.

The diffusion break material layers 95r and 97 may be configured as a plurality of layers. The diffusion break material layers 95r and 97 may include a first diffusion break material layer 95r and a second diffusion break material layer 97 on the first diffusion break material layer 95r. The diffusion break material layers 95r and 97 may include silicon nitride. The etch stopping layer 93 and the diffusion break material layers 95r and 97 may include the same material.

Referring to FIG. 12, the second diffusion break material layer 97 and the first diffusion break material layer 95r may be primarily planarized by using the second mask pattern 94 (see FIG. 16) as an etch stop point. The primary planarization may be performed by using a CMP process.

Subsequently, the mask pattern 94 (see FIG. 16) may be secondarily planarized by using an upper surface of the etch stopping layer 93 (see FIG. 16) as an etch stop point. The secondary planarization may be performed by using a CMP process.

Accordingly, as illustrated in FIG. 11, the diffusion break region SDB buried in the fin recess FR and the gate trench GT may be formed. Furthermore, the etch stopping layer 93 may be formed on the active contacts CA1 to CA5, the gate contacts CB1 to CB3, and some of the gate structures G1 to G6.

FIG. 17 is a schematic plan view layout of a partial region of an integrated circuit semiconductor device EX3 according to an embodiment.

In detail, the integrated circuit semiconductor device EX3 may include a first region P and a second region N. In some embodiments, the first region P may be a p-channel metal-oxide-semiconductor (PMOS) region, and the second region N may be an n-channel metal-oxide-semiconductor (NMOS) region.

The integrated circuit semiconductor device EX3 may include active fins F1 and F2, gate structures G1 to G4, gate contacts (CB) CB1 to CB4, active contacts CA1 to CA5, single diffusion break regions SDB1 and SDB2, double diffusion break regions DB1 to DB3, and dummy spacers 161 and 162.

The active fins F1 and F2 may extend in a first direction (an X direction) parallel to an upper surface of a substrate on which the integrated circuit semiconductor device EX3 may be formed. The active fins F1 and F2 may be arranged apart from one another in a second direction (a Y direction) parallel to an upper surface of a substrate and intersecting the first direction. The active fins F1 and F2 may include a first active fin F1 in the first region P and a second active fin F2 in the second region N. The active fins F1 and F2 may include a long side which is formed in the first direction and a short side which is formed in the second direction.

The gate structures G1 to G4 may extend in the second direction on the active fins F1 and F2. The gate structures G1 to G4 may be arranged apart from one another in the first direction. The gate structures G1 to G4 may include a first gate structure G1, a second gate structure G2, a third gate structure G3, and a fourth gate structure G4, although embodiments are not limited thereto.

The gate contacts (CB) CB1 to CB4 may be on the gate structures G1 to G4 on the active fins F1 and F2. The gate contacts (CB) CB1 to CB4 may be arranged apart from one another in the first direction and the second direction.

The active contacts CA1 to CA5 may be disposed at both sides of the gate structures G1 to G4. The active contacts CA1 to CA5 may extend in the second direction. The active contacts CA1 to CA5 may be arranged apart from each other in the first direction. In an embodiment, the active contact CA3 may be between the single diffusion break regions SDB1 and SDB2. The active contacts CA1 to CA5 may contact the active fins F1 and F2.

The single diffusion break regions SDB1 and SDB2 may be formed between the active contacts CA2 and CA3 and between the active contacts CA4 and CA5, respectively. The single diffusion break regions SDB1 and SDB2 may extend in the second direction. The single diffusion break regions SDB1 and SDB2 may be arranged apart from each other in the first direction. The single diffusion break regions SDB1 and SDB2 may include a first single diffusion break region SDB1 and a second single diffusion break region SDB2.

The double diffusion break regions DB1 and DB2 may include a lower diffusion break region DB1 and upper diffusion break regions DB2 and DB3. The lower diffusion break region DB1 may be formed to cut the second fin F2 in the second region N. The upper diffusion break regions DB2 and DB3 may be disposed on the lower diffusion break region DB1. A width of the lower diffusion break region DB1 may be greater than that of one of the upper diffusion break regions DB2 and DB3.

The upper diffusion break regions DB2 and DB3 may extend long in the second direction and may be arranged in the second direction on the same straight line as the single diffusion break regions SDB1 and SDB2. One side surface of each of the upper diffusion break regions DB2 and DB3 may contact side surfaces of the single diffusion break regions SDB1 and SDB2, respectively.

In some embodiments, the upper diffusion break regions DB2 and DB3 of the double diffusion break regions DB1 to DB3 may not be formed. When the upper diffusion break regions DB2 and DB3 are not formed, the upper diffusion break regions DB2 and DB3 may be replaced with gate structures.

The dummy spacers 161 and 162 may be disposed in the first region P and the second region N. The dummy spacers 161 and 162 may be disposed at one side of each of the single diffusion break regions SDB1 and SDB2 and the upper diffusion break regions DB2 and DB3. The dummy spacers 161 and 162 may be arranged apart from each other in the first direction. The dummy spacers 161 and 162 may extend in the second direction on the active fins F1 and F2.

FIG. 18A is a cross-sectional view of the integrated circuit semiconductor device EX3 shown in FIG. 17 taken along line A-A′, and FIG. 18B is a cross-sectional view of the integrated circuit semiconductor device EX3 shown in FIG. 17 taken along line B-B′.

In detail, the integrated circuit semiconductor device EX3 may include a substrate 101, active regions AR1 and AR2, active fins F1 and F2, gate structures G2 and G3, source and drain regions 120, an interlayer insulation layer 130, an etch stopping layer 140, dummy spacers 161 and 162, gate trenches GT1 to GT4, fin recesses FR1 to FR3, single diffusion break regions SDB1 and SDB2, and double diffusion break regions DB1 to DB3.

The substrate 101 may include a first region P and a second region N (see FIG. 17). The substrate 101 may include a semiconductor material such as Si or Ge, although embodiments are not limited thereto. For example, the substrate 101 may include one or more materials selected from among Si, Ge, SiGe, GaP, GaAs, SiC, SiGeC, InAs, and InP. In an embodiment, the substrate 101 may be an SOI substrate.

The active regions AR1 and AR2 may include a first active region AR1 and a second active region AR2. The first active region AR1 may be disposed in the first region P, and the second active region AR2 may be disposed in the second region N. The active regions AR1 and AR2 may extend long in the first direction (X direction) parallel to an upper surface of the substrate 101. The active regions AR1 and AR2 may be spaced apart from each other in a second direction (Y direction) parallel to the upper surface of the substrate 101 and intersecting with the first direction. The active regions AR1 and AR2 may protrude in a third direction (Z direction) perpendicular to the upper surface of the substrate 101.

The active fins F1 and F2 may include a first active fin F1 and a second active fin F2. The first active fin F1 and the second active fin F2 may be respectively disposed in the first active region AR1 and the second active region AR2.

The active fins F1 and F2 may be arranged apart from each other in the first direction and the second direction in the active regions AR1 and AR2. The active fins F1 and F2 may protrude in the third direction in the active regions AR1 and AR2, respectively. Each of the active regions AR1 and AR2 and the active fins F1 and F2 may be a portion of the substrate 101 and may include an epitaxial layer grown from the substrate 101. In an embodiment, the active regions AR1 and AR2 and the active fins F1 and F2 may include a semiconductor material.

For example, the active regions AR1 and AR2 and the active fins F1 and F2 may include Si or SiGe. In an embodiment, the active regions AR1 and AR2 and the active fins F1 and F2 may include the same semiconductor material as that of the substrate 101. When the substrate 101 includes Si, the active regions AR1 and AR2 and the active fins F1 and F2 may include Si. A device isolation layer may be formed in the substrate 101 except the active regions AR1 and AR2 and the active fins F1 and F2.

The gate structures G2 and G3 may be disposed on the active fins F1 and F2. Each of the gate structures G2 and G3 may include gate electrodes 111 and 112, a gate insulation layer 113, and a gate spacer 114. The gate electrodes 111 and 112 may be stacked as two or more layers. In an embodiment, the gate electrodes 111 and 112 may include a first gate metal layer 111 and a second gate metal layer 112.

In an embodiment, the first gate metal layer 111 may include, for example, at least one of TiN, WN, TiAl, TiAlC, TiAlN, TaN, TIC, TaC, TaCN, TaSiN, or a combination thereof. In an embodiment, the second gate metal layer 112 may include, for example, at least one of W, Al, Co, Ti, Ta, poly-Si, SiGe, or a metal alloy.

The gate insulation layer 113 may be between the gate electrodes 111 and 112 and the active fins F1 and F2. The gate insulation layer 113 may extend in the second direction along a profile of each of the active fins F1 and F2. The gate insulation layer 113 may extend in the third direction along a side surface of each of the gate electrodes 111 and 112.

For example, the gate electrodes 11 and 112 and the gate insulation layer 113 may be formed through a gate replacement process or a gate last process, although embodiments are not limited thereto. The gate insulation layer 113 may include a high-k dielectric material having a dielectric constant which is higher than that of silicon oxide. For example, the gate insulation layer 113 may include HfO₂, ZrO₂, LaO, Al₂O₃, or Ta₂O₅.

The gate spacer 114 may be disposed at opposite sides of the gate insulation layer 113 and the gate electrodes 111 and 112 extending in the second direction. The gate spacer 114 may contact side surfaces of the gate insulation layer 113. The gate spacer 114 may include silicon nitride. For example, the gate spacer 114 may include at least one of silicon nitride, silicon oxynitride, silicon oxide, silicon oxide carbide nitride, and a combination thereof, although embodiments are not limited thereto.

The gate contacts CB1 to CB4 may be disposed on the gate structures G2 and G3 on the active fins F1 and F2. The gate contacts CB1 to CB4 may be electrically connected with the gate structures G2 and G3. The gate contacts CB1 to CB4 may be configured as a metal layer 132. The metal layer 132 may include, for example, W, Al, or Cu.

The source and drain regions 120 may be disposed at opposite sides of the gate structures G2 and G3 in the first direction. The source and drain regions 120 may be in the active fins F1 and F2. That is, the source and drain regions 120 may be in a region where a portion of each of the active fins F1 and F2 is etched.

In an embodiment, the source and drain regions 120 may include Si, SiGe, SiC, or SiP. In an embodiment, the source and drain regions 120 may be formed through epitaxial growth.

The interlayer insulation layer 130 may be on the source and drain regions 120. Also, the interlayer insulation layer 130 may contact an outer sidewall of the gate spacer 114. In an embodiment, the interlayer insulation layer 130 may include at least one of silicon oxide, silicon nitride, silicon oxynitride, and a low-k dielectric material, although embodiments are not limited thereto. The etch stopping layer 140 may be on the gate structures G2 and G3 and the interlayer insulation layer 130. The etch stopping layer 140 may cover upper surfaces of the gate structures G2 and G3 and an upper surface of the interlayer insulation layer 130. For example, the etch stopping layer 140 may include silicon nitride.

The dummy spacers 161 and 162 may be a pair of spacers where inner surfaces thereof face each other. For example, the dummy spacers 161 and 162 may include an outer spacer 161 and an inner spacer 162. The dummy spacers 161 and 162 may be in the first region P and the second region N. Outer sidewalls of dummy spacers 161 and 162 may contact the source and drain regions 120 and the interlayer insulation layer 130.

The active contacts CA1 to CA5 may be on corresponding source and drain regions 120 on the active fins F1 and F2. The active contacts CA1 to CA5 may be electrically connected with the source and drain regions 120. The active contacts CA1 to CA5 may be configured as a metal layer 134. The metal layer 134 may include W, Al, or Cu.

The first and second gate trenches GT1 and GT2 may be in the first region P. The first and second gate trenches GT1 and GT2 may be between the second gate structure G2 and the third gate structure G3. In an embodiment, the first and second gate trenches GT1 and GT2 may be arranged apart from each other in the first direction. The first and second gate trenches GT1 and GT2 may extend long in the second direction along the dummy spacers 161 and 162.

The first fin recess FR1 may be in the first region P. The first fin recess FR1 may be between the active contacts CA2 and CA3. The second fin recess FR2 may be between the active contacts CA3 and CA4. In an embodiment, the first and second fin recesses FR1 and FR2 may be arranged apart from each other in the first direction and the second direction. For example, the first and second fin recesses FR1 and FR2 may be arranged apart from the first active fin F1 in the first direction. Sidewalls of the first and second fin recesses FR1 and FR2 may contact a short side of the first active fin F1.

The sidewalls of the first and second fin recesses FR1 and FR2 may be defined by the first active fin F1. The first and second fin recesses FR1 and FR2 may expose the first active fin F1.

The first and second fin recesses FR1 and FR2 may be under the first and second gate trenches GT1 and GT2. The first and second fin recesses FR1 and FR2 may vertically overlap the first and second gate trenches GT1 and GT2 in terms of a horizontal plane. The first and second fin recesses FR1 and FR2 may extend downward (in the Z direction) from the first and second gate trenches GT1 and GT2 toward the substrate 101 and may cut the first active fin F1. The first and second fin recesses FR1 and FR2 may be merged (connected) with the first and second gate trenches GT1 and GT2 to form a one-body trench space.

The single diffusion break regions SDB1 and SDB2 may be disposed in the first and second gate trenches GT1 and GT2 and the first and second fin recesses FR1 and FR2, in the first region P. The single diffusion break regions SDB1 and SDB2 may include a first single diffusion break region SDB1 disposed in the first gate trench GT1 and the first fin recess FR1 and a second single diffusion break region SDB2 disposed in the second gate trench GT2 and the second fin recess FR2.

The single diffusion break regions SDB1 and SDB2 may fill the first and second gate trenches GT1 and GT2 and the first and second fin recesses FR1 and FR2. The single diffusion break regions SDB1 and SDB2 may contact the first active fin F1 and the first active region AR1 each exposed by the first and second fin recesses FR1 and FR2.

The single diffusion break regions SDB1 and SDB2 may contact the dummy spacers 161 and 162. The single diffusion break regions SDB1 and SDB2 may extend in the third direction from the first and second gate trenches GT1 and GT2, and upper portions of the diffusion break regions SDB1 and SDB2 may be between adjacent etch stopping layers 140. In an embodiment, the single diffusion break regions SDB1 and SDB2 may include silicon nitride.

The third fin recess FR3 may be disposed in the second region N. The third fin recess FR3 may be between the second gate structure G2 and the third gate structure G3. The third fin recess FR3 may be formed so that a sidewall thereof contacts a short side of the second active fin F2.

The sidewall of the third fin recess FR3 may be defined by the second active fin F2. Alternatively, the sidewall of the third fin recess FR3 may be defined by the second active region AR2 and the second active fin F2. The third fin recess FR3 may expose the second active fins F2. A width of the third fin recess FR3 in the first direction may be less than a width between outer sidewalls of the outer spacers 161 of two dummy spacers 161 and 162 adjacent to each other. The width of the third fin recess FR3 in the first direction may be greater than a width between outer sidewalls of the inner spacers 162 of the two dummy spacers 161 and 162 adjacent to each other.

The double diffusion break regions DB1 and DB2 may include a lower diffusion break region DB1 and upper diffusion break regions DB2 and DB3. The lower diffusion break region DB1 may be formed in the third fin recess FR3, in the second region N. The lower diffusion break region DB1 may fill the third fin recess FR3. The lower diffusion break region DB1 may contact the second active fin F2 and the second active region AR2 each exposed by the third fin recess FR3.

The inner spacers 162 of the dummy spacers 161 and 162 may be on the lower diffusion break region DB1. The interlayer insulation layer 130 between the inner spacers 162 may be on the lower diffusion break region DB1. In an embodiment, an upper surface of the lower diffusion break region DB1 may be at the same level as upper ends of the active fins F1 and F2 relative to the upper surface of the substrate 101 as a reference layer.

In an embodiment, the upper surface of the lower diffusion break region DB1 may be at a level which is lower or higher than the upper ends of the active fins F1 and F2, relative to the upper surface of the substrate 101. In an embodiment, the lower diffusion break region DB1 may include silicon oxide or silicon nitride.

The third and fourth gate trenches GT3 and GT4 may be in the second region N. The third and fourth gate trenches GT3 and GT4 may be on a straight line in the second direction with respect to the first and second gate trenches GT1 and GT2. The third and fourth gate trenches GT3 and GT4 may be spaced apart from each other in the first direction.

The third and fourth gate trenches GT3 and GT4 may extend long in the second direction along the dummy spacers 161 and 162, on the second active fin F2 and the lower diffusion break region DB1. Lower surfaces of the third and fourth gate trenches GT3 and GT4 may be defined by the second active fin F2 and the lower diffusion break region DB1. In an embodiment, the third and fourth gate trenches GT3 and GT4 may be merged with the first and second gate trenches GT1 and GT2 arranged on a straight line in the second direction to form a one-body trench space.

The upper diffusion break regions DB2 and DB3 may be in the third and fourth gate trenches GT3 and GT4, in the second region N. The upper diffusion break regions DB2 and DB3 may fill the third and fourth gate trenches GT3 and GT4.

The upper diffusion break regions DB2 and DB3 may contact the dummy spacers 161 and 162. Lower surfaces of the upper diffusion break regions DB2 and DB3 may contact the second active fin F2 and the lower diffusion break region DB1. In an embodiment, the upper diffusion break regions DB2 and DB3 may cover an upper portion of the lower diffusion break region DB1.

The upper diffusion break regions DB2 and DB3 may extend upward, in the Z direction, from the third and fourth gate trenches GT3 and GT4, and upper portions of the upper diffusion break regions DB2 and DB3 may be between adjacent etch stopping layers 140. In an embodiment, upper surfaces of the upper diffusion break regions DB2 and DB3 may be at the same level as an upper surface of the etch stopping layers 140 relative to the upper surface of the substrate 101. In an embodiment, the upper diffusion break regions DB2 and DB3 may include silicon oxide or silicon nitride. The upper diffusion break region DB2 may include the same material as that of the lower diffusion break region DB1.

In an embodiment, the upper diffusion break regions DB2 and DB3 may not be formed. When the upper diffusion break regions DB2 and DB3 are not formed, the upper diffusion break regions DB2 and DB3 may be replaced with gate structures.

In the integrated circuit semiconductor device EX3 according to an embodiment, the etch stopping layer 140 may be on the plurality of active contacts CA1 to CA5 and the plurality of gate contacts CB, in the first active region AR1. In the integrated circuit semiconductor device EX3, the single diffusion break regions SDB1 and SDB2 may be disposed in the first and second gate trenches GT1 and GT2 and the first and second fin recesses FR1 and FR2 between the plurality of active contacts CA2 to CA4.

In the integrated circuit semiconductor device EX3, the lower diffusion break region DB1 may be in the third gate trench GT3 between the active contacts CA2 and CA4, in the second active region AR2, and the upper diffusion break regions DB2 and DB3 may be in the third gate trench GT3 between the active contacts CA2 and CA4. The lower diffusion break region DB1 and the upper diffusion break regions DB2 and DB3 may configure the double diffusion break regions DB1 to DB3. The single diffusion break regions SDB1 and SDB2 and the upper diffusion break regions DB2 and DB3 may be electrically disconnected from each other by the dummy spacers 161 and 162 and the interlayer insulation layer 130.

Accordingly, in the integrated circuit semiconductor device EX3 according to an embodiment, the active contacts CA1 to CA5 and the gate contacts CB may be reliably disposed without being affected by the single diffusion break regions SDB1 and SDB2 and the upper diffusion break regions DB1 and DB2.

Furthermore, in the integrated circuit semiconductor device EX3 according to an embodiment, as described below, the active contacts CA1 to CA5 and the gate contacts CB may be formed, and thereafter the single diffusion break regions SDB1 and SDB2 may be formed, thereby preventing the occurrence of a void in the single diffusion break regions SDB1 and SDB2.

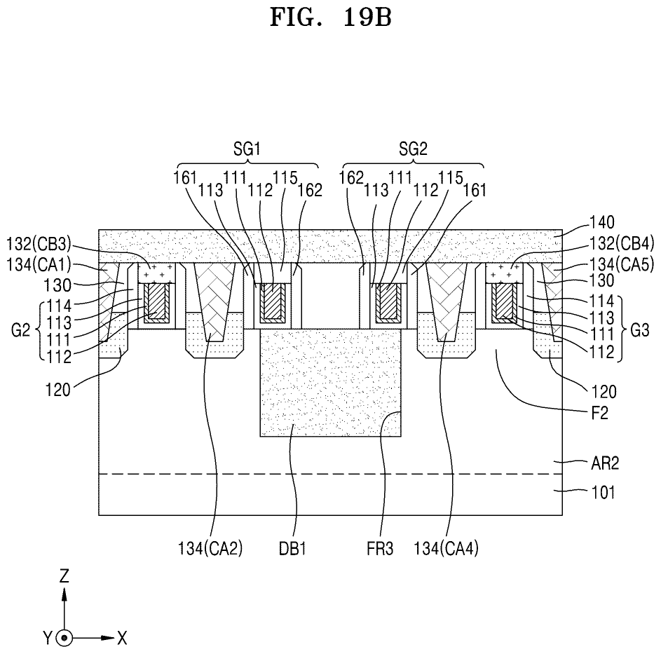

FIGS. 19A to 24B are cross-sectional views depicting intermediate processes in an example method of manufacturing the integrated circuit semiconductor device EX3 of FIGS. 18A and 18B. In FIGS. 19A to 24B, like reference numerals refer to like elements. In FIGS. 19A to 24B, for convenience of description, descriptions given above with reference to FIGS. 17 to 18B will be briefly given or are omitted.

Referring to FIGS. 19A and 19B, processes up to a gate replacement process from a process of forming active fins F1 and F2 on a substrate 101 may be completed. For example, active regions AR1 and AR2 and active fins F1 and F2 may be formed on the substrate 101 including a first region P and a second region N. The active regions AR1 and AR2 and the active fins F1 and F2 may be defined by a device isolation layer.

Furthermore, a third fin recess FR3 may be formed by etching a portion of each of the active region AR2 and the active fin F2, in the second region N of the substrate 101. The third fin recess FR3 may be filled with a lower diffusion break region DB1. Gate structures G2 and G3, sacrificial gate structures SG1 and SG2, source and drain regions 120, and an interlayer insulation layer 130 may be formed on the active fins F1 and F2 and the lower diffusion break region DB1.

The sacrificial gate structures SG1 and SG2 may be between the second and third gate structures G2 and G3. The sacrificial gate structures SG1 and SG2 may include a first sacrificial gate structure SG1 and a second sacrificial gate structure SG2.

Each of the gate structures G2 and G3 may include gate electrodes 111 and 112, a gate insulation layer 113, and a gate spacer 114. The sacrificial gate structures SG1 and SG2 may include the gate electrodes 111 and 112, the gate insulation layer 113, a gate cap layer 115, and dummy spacers 161 and 162.

Subsequently, gate contacts CB1 to CB4 contacting the gate structures G2 and G3 and active contacts CA1 to CA5 contacting the source and drain regions 120 may be formed. The gate contacts CB1 and CB2 may be formed on the gate structures G2 and G3. The gate contacts CB1 to CB4 may include a metal layer 132, and for example, may include W, Al, or Cu. The active contacts CA1 to CA5 may be configured as a metal layer 134. The active contacts CA1 to CA5 may be disposed on the source and drain regions 120 on the active fins F1 and F2. The active contacts CA1 to CA5 may include a metal layer 134, and for example, may include W, Al, or Cu.

Surfaces of the gate contacts CB1 to CB4 and the active contacts CA1 to CA5 may include the same surface. The active contacts CA1 to CA5 may be formed in the interlayer insulation layer 130. Upper surfaces of the gate structures G2 and G3 may be at a level which is lower than upper surfaces of the gate contacts CB1 to CB4 and the active contacts CA1 to CA5, relative to the upper surface of the substrate 101.

An etch stopping layer 140 may be formed on the gate structures G2 and G3, the sacrificial gate structures SG1 and SG2, the gate contacts CB1 to CB5, the active contacts CA1 to CA5, and the interlayer insulation layer 130. The etch stopping layer 140 may include silicon nitride.

Subsequently, open regions OP exposing upper surfaces of the sacrificial gate structures SG1 and SG2 on the first active fin F1 may be formed by patterning the etch stopping layer 140 through a photolithography process.

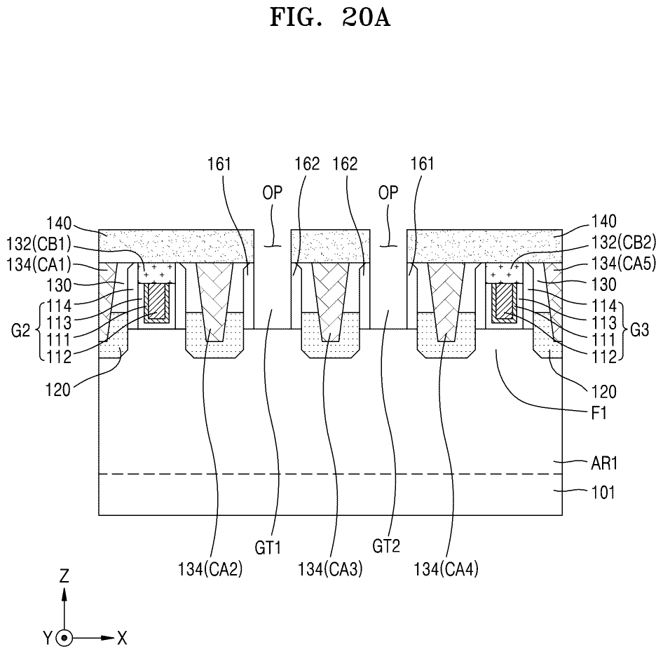

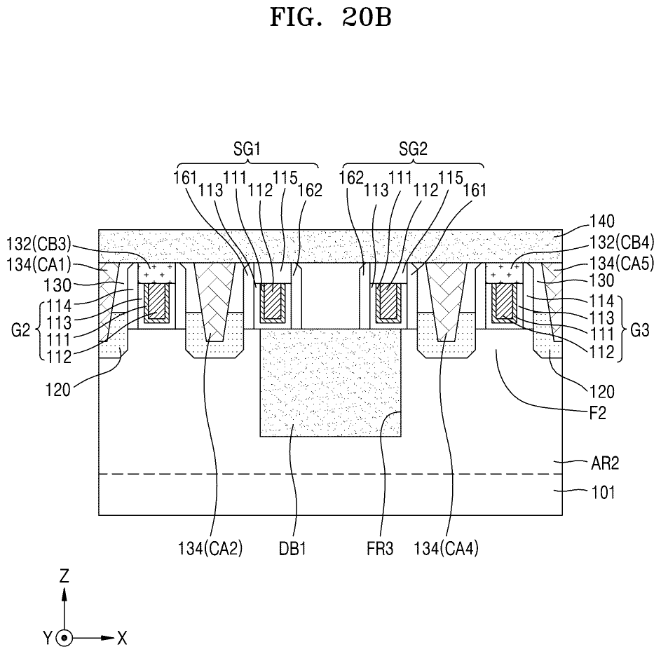

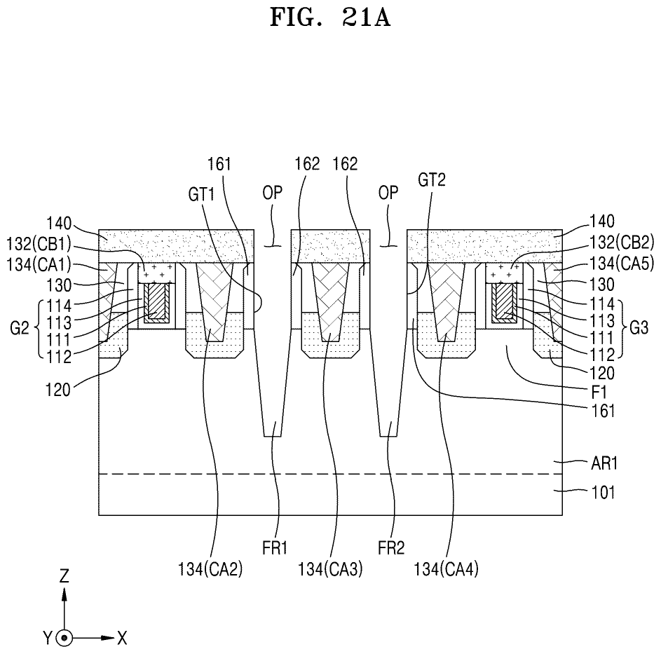

Referring to FIGS. 20A and 20B, the gate cap layer 115, the gate electrodes 111 and 112, and the gate insulation layer 113 of the sacrificial gate structures SG1 and SG2 on the first active fin F1 may be sequentially etched through the open regions OP and may thus be removed. Therefore, the first and second gate trenches GT1 and GT2 may be formed, with the dummy gate spacers 161 and 162 defining at least a portion of sidewalls of the first and second gate trenches GT1 and GT2.

Inne surfaces of sidewalls of the dummy spacers 161 and 162 and an upper portion of the first active fin F1 may be exposed through the first and second gate trenches GT1 and GT2. The gate cap layer 115, the gate electrodes 111 and 112, and the gate insulation layer 113 may be removed by anisotropic etching and/or isotropic etching.

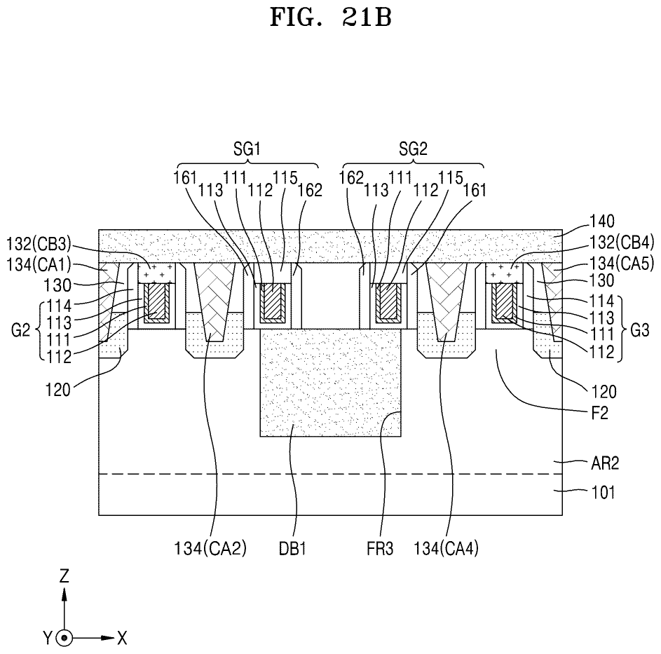

Referring to FIGS. 21A and 21B, the first active fin F1 where an upper portion is exposed through the first and second gate trenches GT1 and GT2 may be etched, and thus, first and second fin recesses FR1 and FR2 may be formed, in the first active region AR.

The first and second fin recesses FR1 and FR2 may be formed to extend downward in the third direction (Z direction) from the first and second gate trenches GT1 and GT2. The first and second fin recesses FR1 and FR2 may be merged with the first and second gate trenches GT1 and GT2, respectively, to form a one-body connected space.

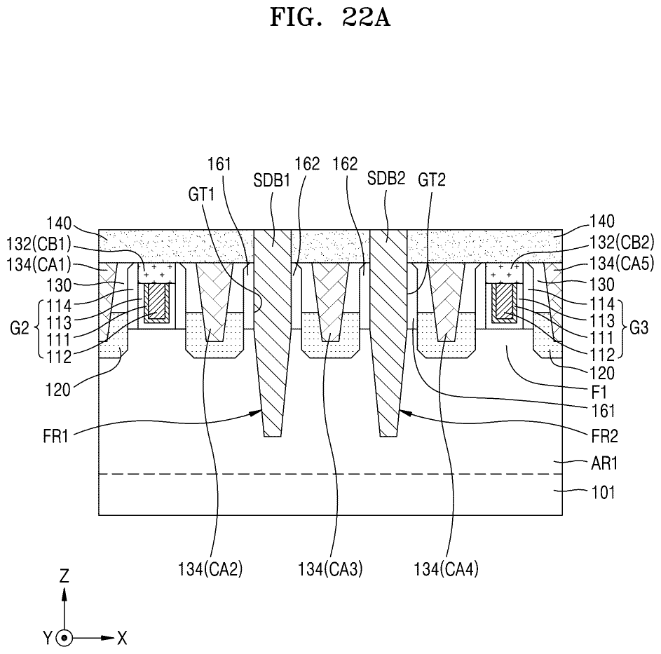

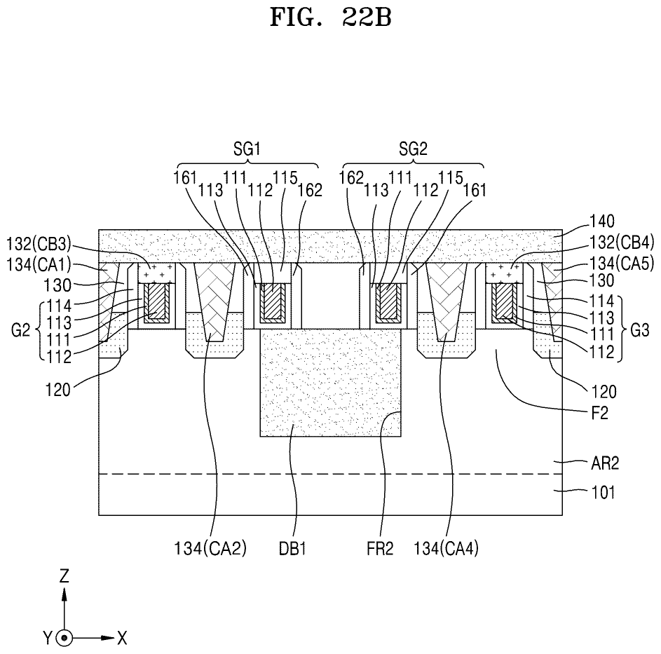

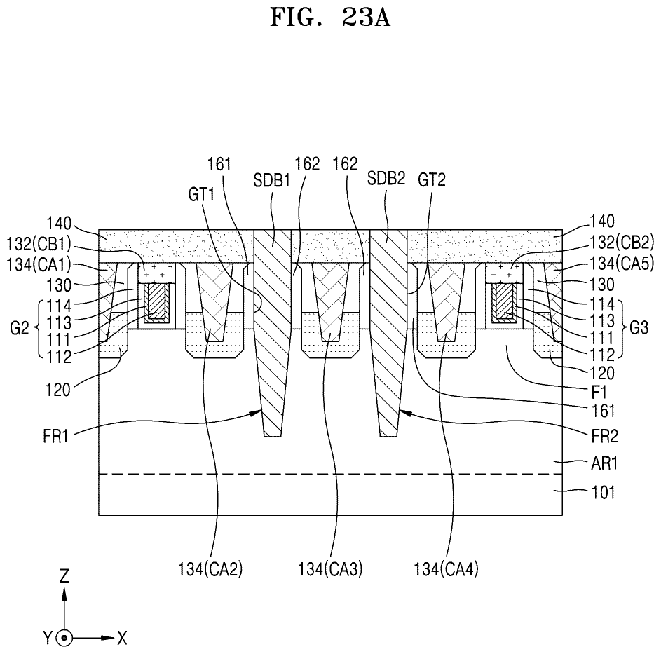

Referring to FIGS. 22A and 22B, single diffusion break regions SDB1 and SDB2 may be formed in the first and second fin recesses FR1 and FR2 and the first and second gate trenches GT1 and GT2 of the first active region AR1. The single diffusion break regions SDB1 and SDB2 may completely fill the first and second gate trenches GT1 and GT2 and the first and second fin recesses FR1 and FR2. The single diffusion break regions SDB1 and SDB2 may fill up to the open region OP of the etch stopping layer 140.

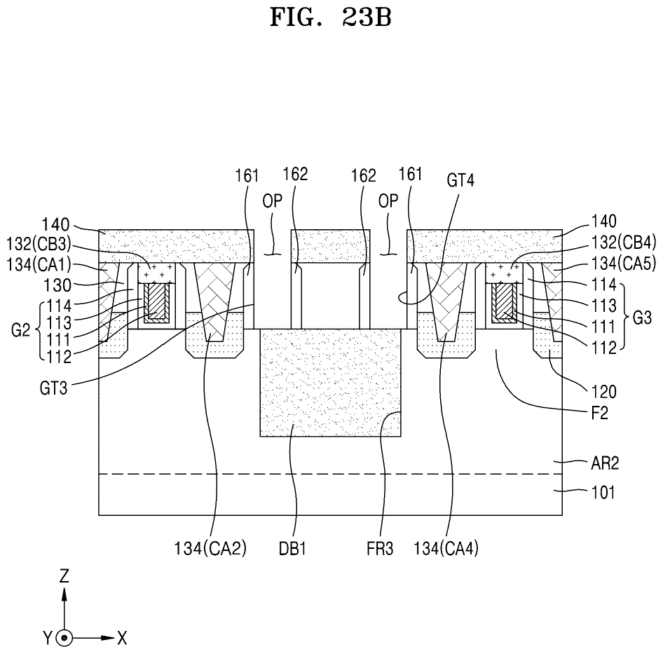

Referring to FIGS. 23A and 23B, open regions OP exposing upper surfaces of the sacrificial gate structures SG1 and SG2 in the second active region AR2 may be formed by patterning the etch stopping layer 140 of the second active region AR2. Patterning of the etch stopping layer 140 of the second active region AR2 may be performed through a photolithography process.

The gate cap layer 115, the gate electrodes 111 and 112, and the gate insulation layer 113 of the sacrificial gate structures SG1 and SG2 may be sequentially removed through the open regions OP. The gate cap layer 115, the gate electrodes 111 and 112, and the gate insulation layer 113 may be removed, and thus, third and fourth gate trenches GT3 and GT4 may be formed. The third and fourth gate trenches GT3 and GT4 may expose sidewalls of the dummy spacers 161 and 162, an upper portion of the lower diffusion break region DB1, and side surfaces of the single diffusion break regions SDB1 and SDB2.

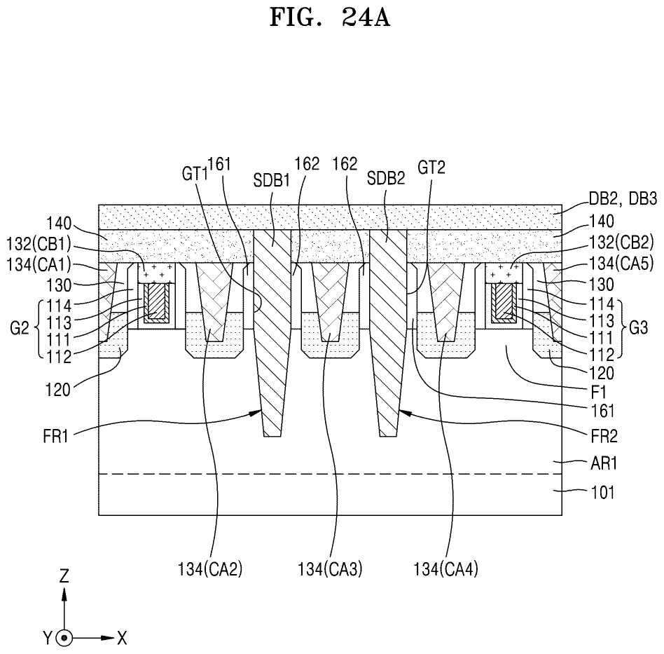

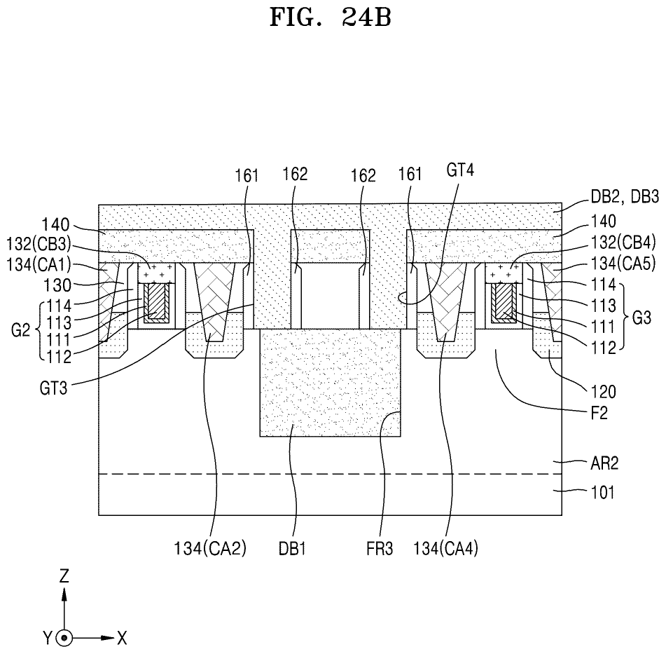

Referring to FIGS. 24A and 24B, upper diffusion break regions DB2 and DB3 may be formed in the second active region AR2. The upper diffusion break regions DB2 and DB3 may fill the third and fourth gate trenches GT3 and GT4, respectively. The upper diffusion break regions DB2 and DB3 may fill the open regions OP of the etch stopping layer 140. The upper diffusion break regions DB2 and DB3 may cover an upper surface of the etch stopping layer 140. The upper diffusion break regions DB2 and DB3 may cover an upper portion of the lower diffusion break region DB1.

The upper diffusion break regions DB2 and DB3 may cover an upper surface of the single diffusion break regions SDB1 and SDB2. One side surface of each of the upper diffusion break regions DB2 and DB3 may contact one side surface of a corresponding one of the single diffusion break regions SDB1 and SDB2. The upper diffusion break regions DB2 and DB3 may fill up to the open regions OP of the etch stopping layer 140.

Subsequently, as illustrated in FIGS. 18A and 18B, the upper diffusion break regions DB2 and DB3 may be planarized, for example through a planarization process, and thus the upper diffusion break regions DB2 and DB3 on the etch stopping layer 140 may be removed and an upper surface of the etch stopping layer 140 may be exposed. Through such a process, the integrated circuit semiconductor device EX3 of FIGS. 18A and 18B may be finished.

In some embodiments, the upper diffusion break regions DB2 and DB3 may not be formed.

When the upper diffusion break regions DB2 and DB3 are not formed, a process of forming the third and fourth gate trenches GT3 and GT4 of FIGS. 23B and 24B may be omitted. When the upper diffusion break regions DB2 and DB3 are not formed, the sacrificial gate structures SG1 and SG2 may not be removed and may be intactly disposed in the integrated circuit semiconductor device EX3.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. An integrated circuit semiconductor device, comprising:
a substrate;
an active fin on the substrate;
a plurality of gate structures spaced apart from one another on the active fin in a first direction parallel to an upper surface of the substrate, each of the plurality of gate structures extending in a second direction parallel to the upper surface of the substrate and intersecting the first direction;
an interlayer insulation layer configured to electrically insulate the plurality of gate structures on the active fin;
a plurality of gate contacts spaced apart from one another on the plurality of gate structures;
a plurality of active contacts spaced apart from one another at opposite sides of the plurality of gate structures in the first direction, each of the plurality of active contacts passing through the interlayer insulation layer in a third direction perpendicular to the upper surface of the substrate and contacting the active fin;
an etch stopping layer on the plurality of gate structures, the interlayer insulation layer, the plurality of gate contacts, and the plurality of active contacts; and
a plurality of diffusion break regions between the plurality of active contacts in the first direction, the plurality of diffusion break regions at least partially filling gate trenches passing through the etch stopping layer and the interlayer insulation layer in the third direction and at least partially filling fin recesses cutting the active fin under the gate trenches.

2. The integrated circuit semiconductor device of claim 1, wherein the active fin further comprises a plurality of source and drain regions spaced apart from each other at opposite sides of the plurality of gate structures in the first direction, and the plurality of active contacts electrically contact the plurality of source and drain regions.

3. The integrated circuit semiconductor device of claim 1, wherein each of the plurality of gate structures comprises gate electrodes and gate spacers formed on opposite sidewalls of the gate electrodes.

4. The integrated circuit semiconductor device of claim 3, wherein the plurality of active contacts pass through the interlayer insulation layer and the gate spacers and electrically contact the active fin.

5. The integrated circuit semiconductor device of claim 3, wherein the plurality of diffusion break regions are buried in the gate trenches passing through the etch stopping layer, the interlayer insulation layer, and the gate spacers and in the fin recesses connecting with the gate trenches under the gate trenches.

6. The integrated circuit semiconductor device of claim 1, wherein the plurality of diffusion break regions and the etch stopping layer comprise a same material.

7. The integrated circuit semiconductor device of claim 1, wherein lower ends of the plurality of diffusion break regions are at a level which is lower than lower ends of the plurality of active contacts relative to the upper surface of the substrate.

8. The integrated circuit semiconductor device of claim 1, wherein the plurality of diffusion break regions comprise single diffusion break regions configured as one insulation layer.

9. An integrated circuit semiconductor device, comprising:
a substrate;
a plurality of active fins extending in a first direction on the substrate and arranged apart from one another in a second direction intersecting the first direction, the first and second directions being parallel to an upper surface of the substrate;
a plurality of gate structures extending in the second direction on the plurality of active fins and arranged apart from one another in the first direction;
an interlayer insulation layer configured to insulate the plurality of gate structures on the plurality of active fins;
a plurality of gate contacts on the plurality of gate structures and arranged apart from one another in the first direction and the second direction;
a plurality of active contacts extending in the second direction at both sides of the plurality of gate structures arranged apart from one another in the first direction, the plurality of active contacts passing through the interlayer insulation layer and contacting the plurality of active fins;
an etch stopping layer on the plurality of gate structures, the interlayer insulation layer, the plurality of gate contacts, and the plurality of active contacts; and
a plurality of diffusion break regions between the plurality of active contacts, the plurality of diffusion break regions being buried in gate trenches passing through the etch stopping layer and the interlayer insulation layer and in fin recesses cutting the plurality of active fins under the gate trenches.

10. The integrated circuit semiconductor device of claim 9, wherein the plurality of active fins further comprise a plurality of source and drain regions arranged apart from each other at opposite sides of the plurality of gate structures, and the plurality of active contacts electrically contact the plurality of source and drain regions.

11. The integrated circuit semiconductor device of claim 9, wherein the plurality of gate structures comprise gate electrodes and gate spacers on opposite sidewalls of the gate electrodes, and the plurality of active contacts pass through the interlayer insulation layer and the gate spacers in a third direction perpendicular to the upper surface of the substrate and electrically contact the plurality of active fins.

12. The integrated circuit semiconductor device of claim 9, wherein the plurality of gate structures comprise gate electrodes and gate spacers on opposite sidewalls of the gate electrodes, and the plurality of diffusion break regions are buried in the gate trenches passing through the etch stopping layer, the interlayer insulation layer, and the gate spacers and in the fin recesses connecting with the gate trenches under the gate trenches.

13. The integrated circuit semiconductor device of claim 9, wherein the plurality of diffusion break regions comprise void-free diffusion break regions where a void is not formed, and the plurality of diffusion break regions comprise single diffusion break regions configured as one insulation layer.

14. The integrated circuit semiconductor device of claim 9, wherein lower ends of the plurality of diffusion break regions are at a level which is lower than lower ends of the plurality of active contacts relative to the upper surface of the substrate.

15. An integrated circuit semiconductor device, comprising:
a substrate including a first region and a second region;
a plurality of active fins extending in a first direction in the first region and the second region and arranged apart from one another in a second direction intersecting the first direction, the first and second directions being parallel to an upper surface of the substrate;
a plurality of gate structures extending in the second direction on the plurality of active fins in the first region and the second region and arranged apart from one another in the first direction;
an interlayer insulation layer configured to insulate the plurality of gate structures on the plurality of active fins in the first region and the second region;
a plurality of gate contacts on the plurality of gate structures on the plurality of active fins in the first region and the second region and arranged apart from one another in the first direction and the second direction;
a plurality of active contacts extending in the second direction at opposite sides of the plurality of gate structures in the first region and the second region and arranged apart from one another in the first direction, the plurality of active contacts passing through the interlayer insulation layer in a third direction perpendicular to the upper surface of the substrate and electrically contacting the plurality of active fins;
an etch stopping layer on the plurality of gate structures, the interlayer insulation layer, the plurality of gate contacts, and the plurality of active contacts in the first region and the second region;
a plurality of single diffusion break regions between the plurality of active contacts of the first region, the plurality of single diffusion break regions in first gate trenches passing in the third direction through the etch stopping layer and the interlayer insulation layer and at least partially filling first fin recesses cutting the plurality of active fins under the first gate trenches; and
a plurality of double diffusion break regions between the plurality of active contacts of the second region, the plurality of double diffusion break regions including an upper diffusion break region in second gate trenches passing in the third direction through the etch stopping layer and the interlayer insulation layer and a lower diffusion break region in second fin recesses cutting the plurality of active fins under the upper diffusion break region.

16. The integrated circuit semiconductor device of claim 15, wherein the upper diffusion break region comprises a first upper diffusion break region and a second upper diffusion break region, and the first upper diffusion break region and the second upper diffusion break region contact the lower diffusion break region.

17. The integrated circuit semiconductor device of claim 15, wherein a lower end of the upper diffusion break region contacts an upper end of the lower diffusion break region.

18. The integrated circuit semiconductor device of claim 15, wherein a width of the lower diffusion break region is greater than a width of the upper diffusion break region in a plane parallel to the upper surface of the substrate.

19. The integrated circuit semiconductor device of claim 15, wherein the plurality of gate structures comprise gate electrodes and gate spacers formed on opposite sidewalls of the gate electrodes, and
the plurality of single diffusion break regions are in the first gate trenches passing through the etch stopping layer, the interlayer insulation layer, and the gate spacers and in the first fin recesses connecting with the first gate trenches under the first gate trenches.

20. The integrated circuit semiconductor device of claim 15, wherein the plurality of gate structures comprise gate electrodes and gate spacers formed on opposite sidewalls of the gate electrodes, and
the upper diffusion break region is in the second gate trenches passing through the etch stopping layer, the interlayer insulation layer, and the gate spacers, and the lower diffusion break region is in the second fin recesses connecting with the second gate trenches under the second gate trenches.
